(19) United States
(12) Patent Application Publication
(10) Pub. No.: US 2010/0147381 A1
(43) Pub. Date: Jun. 17, 2010

(54) Ultra and very high efficiency solar cells

(76) Inventors: Michael W. Haney, Oak Hill, VA (US); Michael J. McFadden, San Antonio, TX (US)

Correspondence Address: POTTER ANDERSON & CORROON LLP;ATTN: JANET E. REED, PH.D., P.O. BOX 951, WILMINGTON, DE, 19899-0951, US

(21) Appl. No.: 11/919,836

(22) PCT Filed: May 3, 2006
(86) PCT No.: PCT/US2006/016870

§ 371 Date: Nov. 2, 2007

Related U.S. Application Data
(60) Provisional application No. 60/699,136, filed on Jul. 13, 2005.
(60) Provisional application No. 60/726,907, filed on Oct. 14, 2005.

(51) Int. Cl. H01L 31/00

(52) U.S. Cl. 136/259

(57) ABSTRACT

The present invention is an apparatus and method for the realization of a photovoltaic solar cell that is able to achieve greater than 50% efficiency and can be manufactured at low cost on a large scale. The apparatus of the present invention is an integrated optical and solar cell design that allows a much broader choice of materials, enabling high efficiency, the removal of many existing cost drivers, and the inclusion of multiple other innovations.

### BACKGROUND INVENTION

The present invention is directed toward the development of very-high-efficiency solar cells. The present invention is based on a significantly increased materials and device architecture space. Specifically the present invention utilizes a thin static concentrator that enables achievement of 54% efficiency as well as a diverse set of approaches for low cost manufacturing.

### SUMMARY OF THE INVENTION

The present invention is an apparatus and method for the realization of a solar cell that is close to its modeled limit and is manufacturable at low cost on a large scale. The present invention is an integrated optical and solar cell design, which dramatically increases the design space. Integrating the optical design with the solar cell design allows a much broader choice of materials, enabling high efficiency, the removal of many existing cost drivers, and the inclusion of multiple other innovations.

The present invention applies innovations that leverage the high performance and stability of existing best-practices in solar cell technology while reducing costs. A two-tiered approach to the present invention starts with a relatively low technical risk design to achieve 45% efficiency and then builds on that platform to achieve efficiencies >54% while developing new enabling technologies that will integrate these new concepts into low-cost, ultra-high-performance solar cells.

The present invention comprises at least two optical design and device architectures. First, a Lateral Architecture splits the light into spectral components, allowing the utilization of individual devices optimized for each part of the spectrum. This architecture and design circumvents many material constraints by avoiding lattice and current matching constraints and by eliminating spectral mismatch losses. Key to this architecture/design is the independent optimization of each of the energy conversion junctions and independent electrical contacts that eliminate spectral mismatch.

Second, a Vertical Architecture with an independently contacted vertical junction stack provides a parallel approach to the Lateral Architecture solar cell. This architecture/design realizes benefits similar to those of the Lateral Architecture solar cell but with a vertical stack. In particular, each solar cell in the vertical stack can be independently contacted, thus avoiding current matching issues, increasing the flexibility in material choice and avoiding spectral mismatch.

The development of the present invention was driven by a disciplined design approach that started with the thermodynamic limits as a boundary condition. Each part of the design is analyzed for its ability to achieve all of the required high-efficiency solar cell parameters: light absorption, minority carrier collection, voltage generation, and ideal diode (fill factor). Optimally, the preferred design voltage generation for each part of the spectrum is achieved.

In addition, the present invention leverages state-of-the-art technologies and provides a high performance baseline. Further, the present invention starts with the highest-performance solar cell technologies and adds new device architectures and process technologies as they demonstrate (1) higher performance at a similar cost or (2) lower cost at the same performance. Moreover, the integration of optical design and semiconductor device architectures based on static concentration leads to a robust design and technology space with many technology options.

One embodiment of the present invention is a apparatus for an efficient solar cell, comprising: a chromatic dispersion element; an optical condenser; and a plurality of spectrally separated solar cells, wherein the chromatic dispersion element, optical condenser and plurality of spectrally separated solar cells are configured in a lateral architecture and the chromatic dispersion element splits incident light into a plurality of spectral components for processing by the apparatus.

Preferably, the above embodiment further comprises the optical condenser is of a tiled nature. In addition, preferably in the above embodiment the chromatic dispersion element, optical condenser and spectrally separated solar cells that are each optimized for processing each of the plurality spectral components incident thereon. Further, preferably in the above embodiment the optical condenser captures a majority of diffuse light of the incident light and the optical condenser is a static concentrator. Further, preferably in the above embodiment concentration of the static concentrator is in a range from 10× to 200×. Furthermore, in the above embodiment each of the plurality of solar cells is placed under each of the plurality of spectral components. Moreover, preferably in the above embodiment the plurality of spectrally separated solar cells is individually contacted to a voltage bus.

In another embodiment of the present invention is a apparatus for an efficient solar cell, comprising: a chromatic dispersion element; an optical condenser; and a plurality of spectrally separated solar cells, wherein the chromatic dispersion element, optical condenser and plurality of spectrally separated solar cells, are configured in a vertical architecture that splits incident light into a plurality of spectral components for processing by the apparatus, and each spectrally separated solar cell is a vertical stack.

Preferably, in the above embodiment further the optical condenser is of a tiled nature. In addition, preferably in the above embodiment the chromatic dispersion element, optical condenser and spectrally separated solar cells that are each optimized for processing each of the plurality spectral components incident thereon. Further, preferably in the above embodiment the optical condenser captures a majority of diffuse light of the incident light and the optical condenser is a static concentrator. Further, preferably in the above embodiment concentration of the static concentrator is in a range from 10× to 200×. Furthermore, preferably in the above embodiment each of the plurality of solar cells is placed under each of the plurality of spectral components. Moreover, preferably in the above embodiment the plurality of spectrally separated solar cells is individually contacted to a voltage bus.

In yet another embodiment, the present invention is an apparatus for a photovoltaic solar cell, comprising: a collector tile; a first prism; a second prism; a spectral splitter; a static concentrator; and at least one of a lateral architecture and vertical architecture using optical interconnects and solar cell device structures, wherein the first and second prisms are at an input aperture of the collector tile, the first prism is very highly dispersive prism and the second prism is low dispersion prism.

Preferably, in the above embodiment the spectral splitter is configured to divide at least one of light and a solar beam into high energy, mid-energy and low energy regions. In addition, preferably in the above embodiment the static concentrator further comprises: micro-trackers configured to allow alignment of at least one of light and a solar beam to the spectral splitter.

Further, preferably in the above embodiment of the lateral architecture is further configured to: split at least one of light and a solar beam into a plurality of spectral components; utilize individual devices optimized for each of the plurality of spectral components; independently optimize each energy conversion junction and independent electrical contacts; include additional optical elements that are integrated with the static concentrator, to split the spectrum of at least one of a light and solar beam into component colors; place separate solar cells under each of the component colors, and contact each solar cell separately; and contact individual solar cells with individual voltage busses, wherein the vertical architecture is configured to: independently contact a vertical junction stack; provide a parallel approach to the lateral architecture of the photovoltaic solar cell; and provide a vertically-integrated device with solar cells that are independently contacted.

Furthermore, preferably in the above embodiment the device structures further comprise: multiple junction solar cells configured with materials for high performance for wavelengths in ranges close to the band gap of the materials and configured with different materials for high, mid- and low-energy photons, wherein the materials for high performance further comprise: ternary compounds from the GaInAsP materials system for high-energy photons; silicon for mid-energy photons; and InGaAs or other thermophotovoltaic (TPV) materials for the low energy photons; wherein other materials for the multiple junction solar cell further comprise: III-nitride material system; In-rich defect tolerant III-V materials for the high energy photons; and Si/Ge materials system for low energy photons.

Moreover, preferably in the above embodiment the materials for the solar cells may further comprise at least one of multiple exciton generation and multiple energy level (intermediate band) solar cells, in conjunction with self-assembled fabrication technologies.

In yet another embodiment, the present invention is a method for constructing a solar cell, comprising: coating a glass substrate with p+ silicon and re-crystallizing; depositing and forming a selective wavelength light trapping layer on the p+ silicon; growing an n-type silicon on the p+ silicon and re-crystallizing; selectively growing an area of GaP as a buffer layer; on the re-type silicon; growing a GaAsP solar cell; growing a GaInP solar cell; growing an InGaN solar cell; forming electrical contacts to each solar cell; and depositing an anti-reflection layer matched to the concentrator (and dispersion) optics.

In addition, preferably the above embodiment further comprising: coating another piece of glass with n-type silicon and re-crystallizing; growing a Silicon: germanium alloy (of Si:Ge quantum dot); growing a silicon p+ junction; depositing a light trapping structure; and forming electrical contacts.

### BRIEF DESCRIPTION OF DRAWINGS

FIG. 1 shows an exemplary integrated optical architecture/design flow diagram for semiconductor devices based on static concentration.

FIG. 2 shows an exemplary diagram illustrating the method of the present invention for implementing ultra-high efficiency solar cells.

FIG. 3 shows an exemplary plot of efficiency as the number of band gaps for the Air Mass 1.5G spectrum, for 1×, 10×, 20×, 50× concentration.

FIG. 4 shows the requirements for solar cell efficiencies >50%.

FIG. 5 shows an exemplary lateral solar cell architecture.

FIG. 6 shows an exemplary vertical solar cell architecture.

FIG. 7 shows an exemplary overview of proposed architectures and device structures of the present invention.

FIG. 8 shows an exemplary multiple exciton generation solar cell.

FIG. 9 shows an exemplary PC1D modeling results showing path to low-cost, high performance solar cell by using n-base, thin structures.

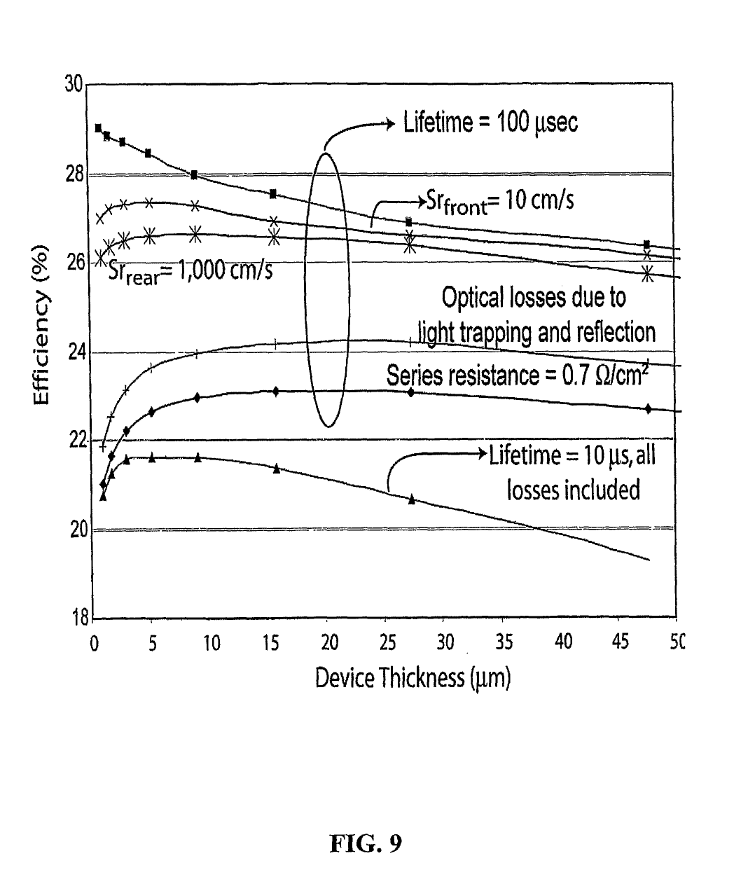

FIG. 10 shows an exemplary thin p-base solar cell using low cost materials.

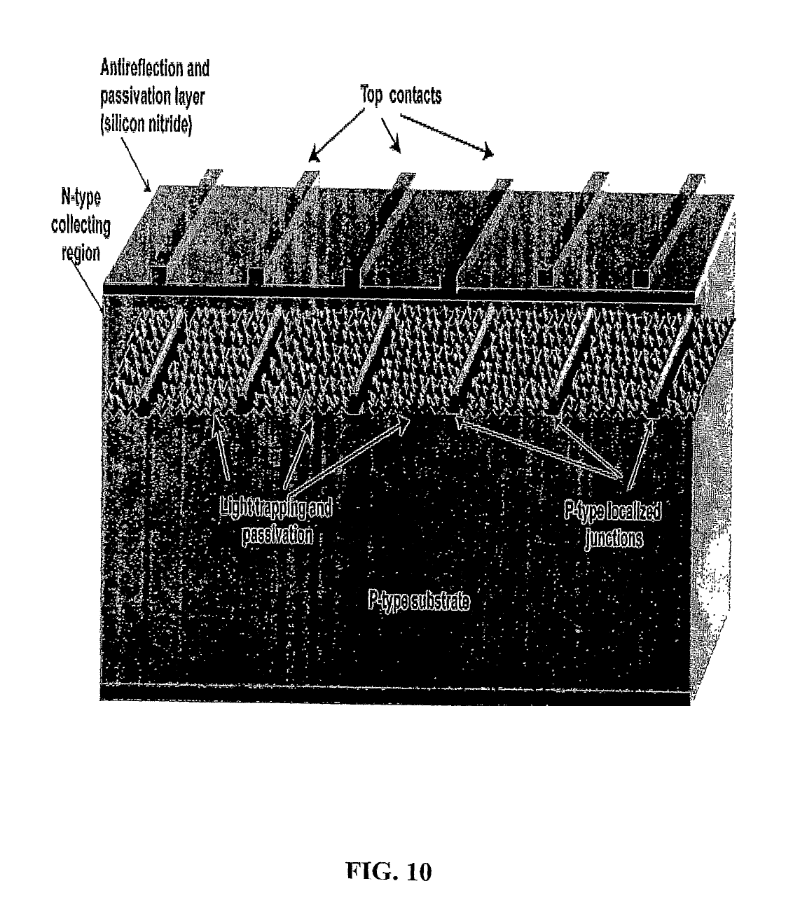

FIG. 11 shows two exemplary configurations for a multiple energy level solar cell.

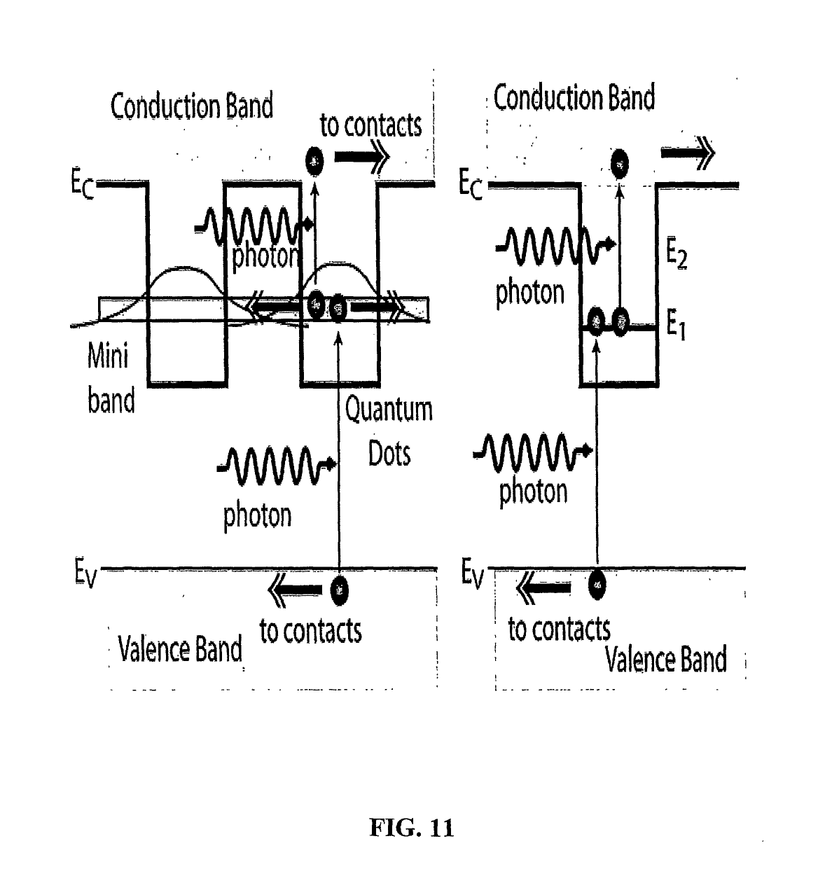

FIG. 12 shows an exemplary quantum yield for exciton formation from a single photon vs. photon energy expressed as the ratio of the photon energy to the QD band gap for three PbSe QD sizes and one PbS.

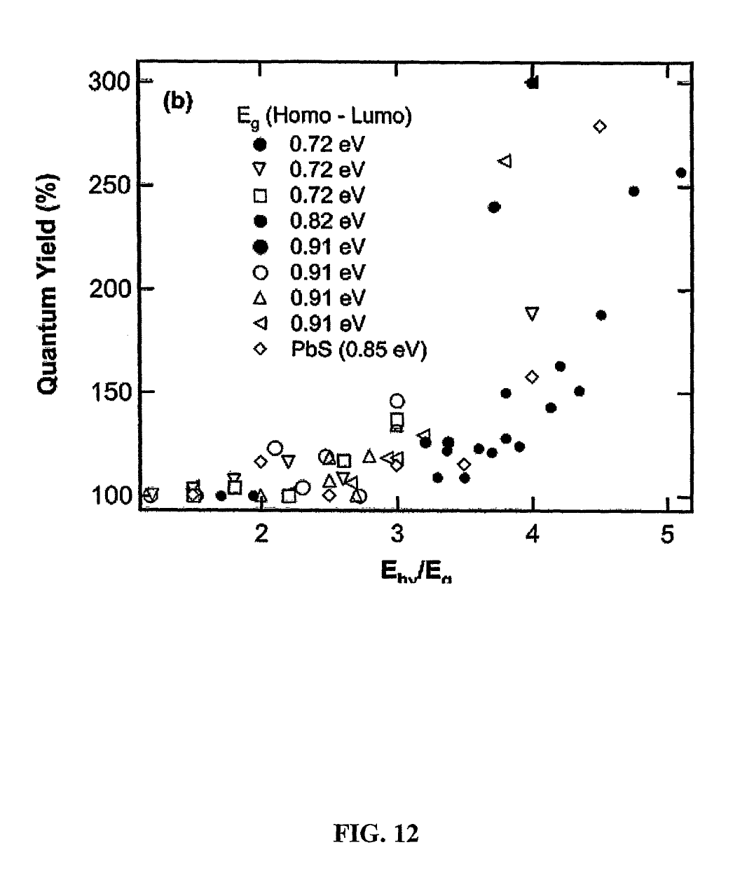

FIG. 13 shows an exemplary selective energy contacts based contacting quantum dot arrays.

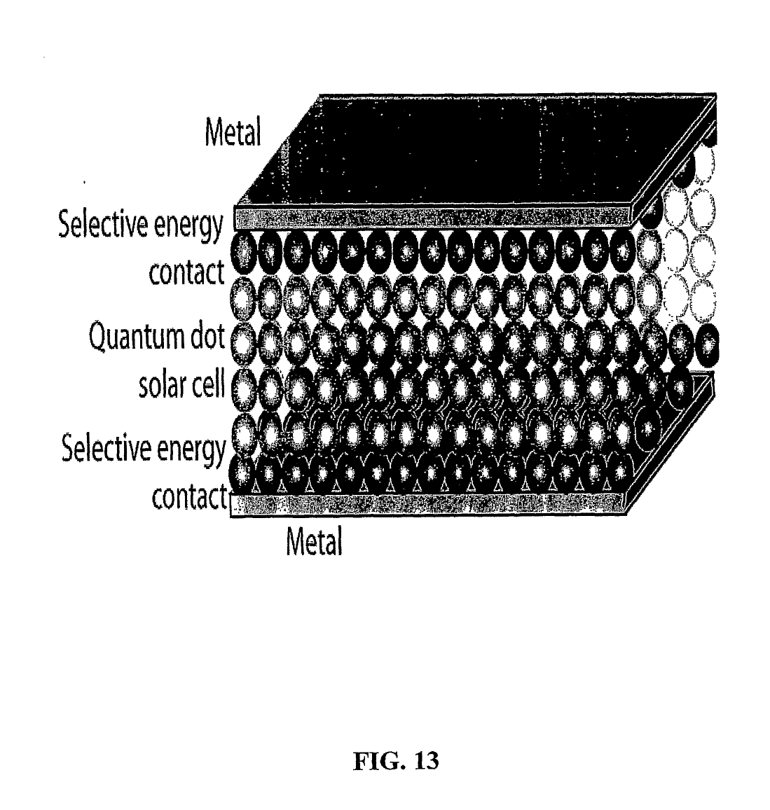

FIG. 14 shows examples of diverse approaches to expand technology options of the present invention (part I).

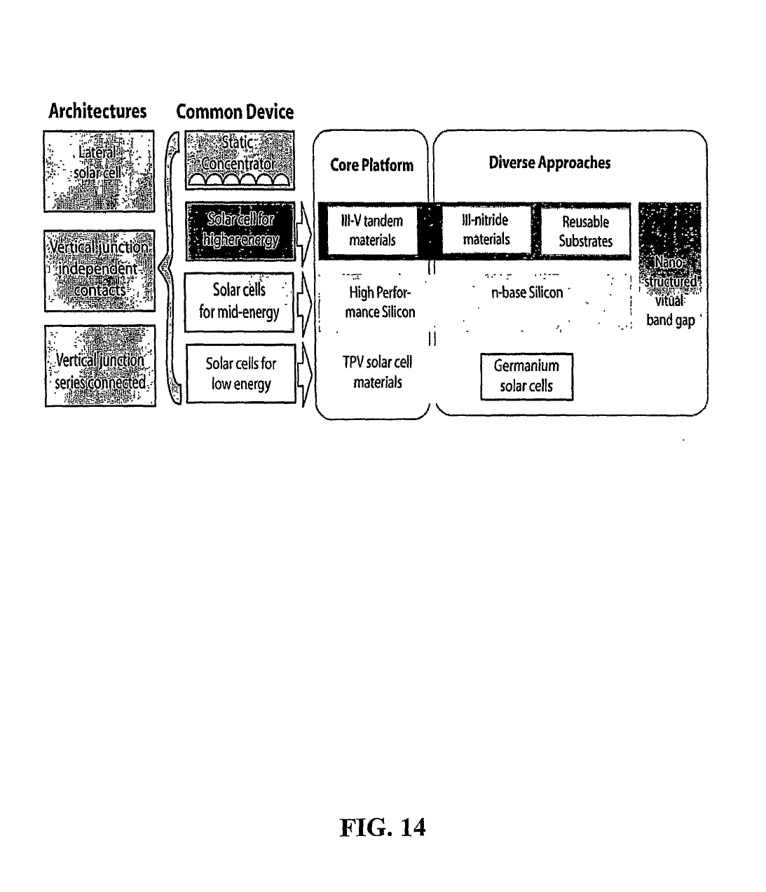

FIG. 15 shows examples of diverse approaches to expand technology options of the present invention (part II).

FIG. 16 shows an exemplary band gaps for a 6J Solar Cell.

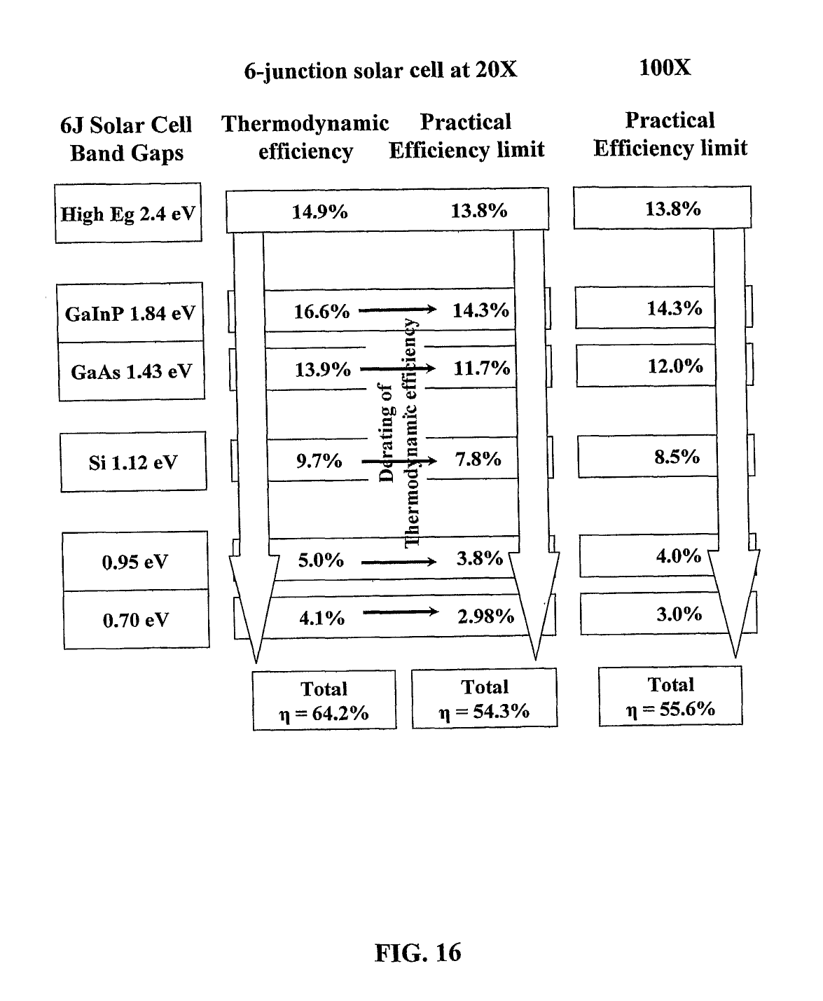

FIG. 17 shows an exemplary schematic for a lateral optical system.

### DETAILED DESCRIPTION

Approaching the thermodynamic efficiency limits is the ultimate goal of any energy conversion process, and mature energy technologies operate at approximately 85% of their ideal efficiency. One-junction silicon solar cells have been under intensive development for 50 years and are approaching this milestone, although substantial improvements are still required to allow commercial devices to reach the performance of laboratory solar cells. These advances in silicon solar cells have fueled sustained, rapid growth in terrestrial photovoltaics, but a one-junction solar cell captures only about half of the theoretical potential for solar energy conversion, limiting the photovoltaics to those applications where low power density is acceptable. New high performance approaches allow expanded range of applications such as mobile power for the Warfighter.

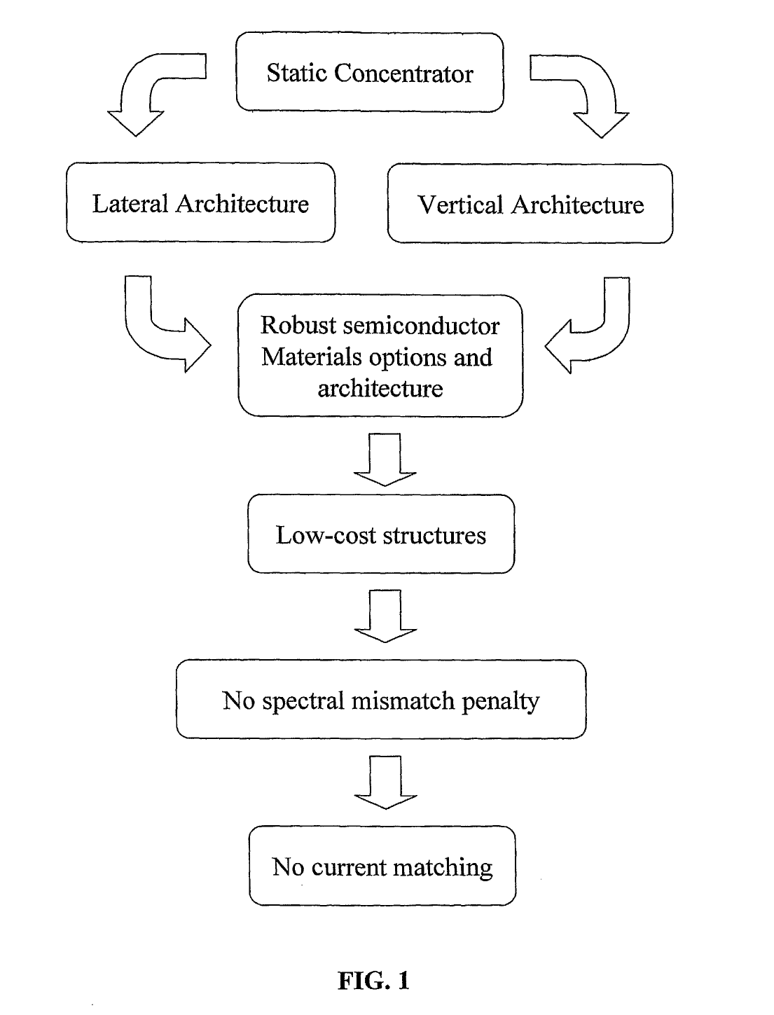

To overcome existing barriers to high-performance manufacturable photovoltaics a fundamentally new technology is required. The magnitude of the problem—tripling existing terrestrial solar cell efficiency or increasing space cell efficiency by 66% while reducing its cost by 100—requires multiple innovations. As shown in the flow diagram of FIG. 1, the method of the present invention integrates the optical, interconnect and solar cell design, which dramatically increases the design space for high performance photovoltaics in terms of materials, device structures and manufacturing technology. As noted in FIG. 1, the method of the present invention provides multiple benefits, including increased theoretical efficiency, new architectures which circumvent existing material/cost trade-offs, improved performance from non-ideal materials, device designs that can more closely approach ideal performance limits for existing solar technology (including silicon solar cells), reduced spectral mismatch losses and increased flexibility in material choices.

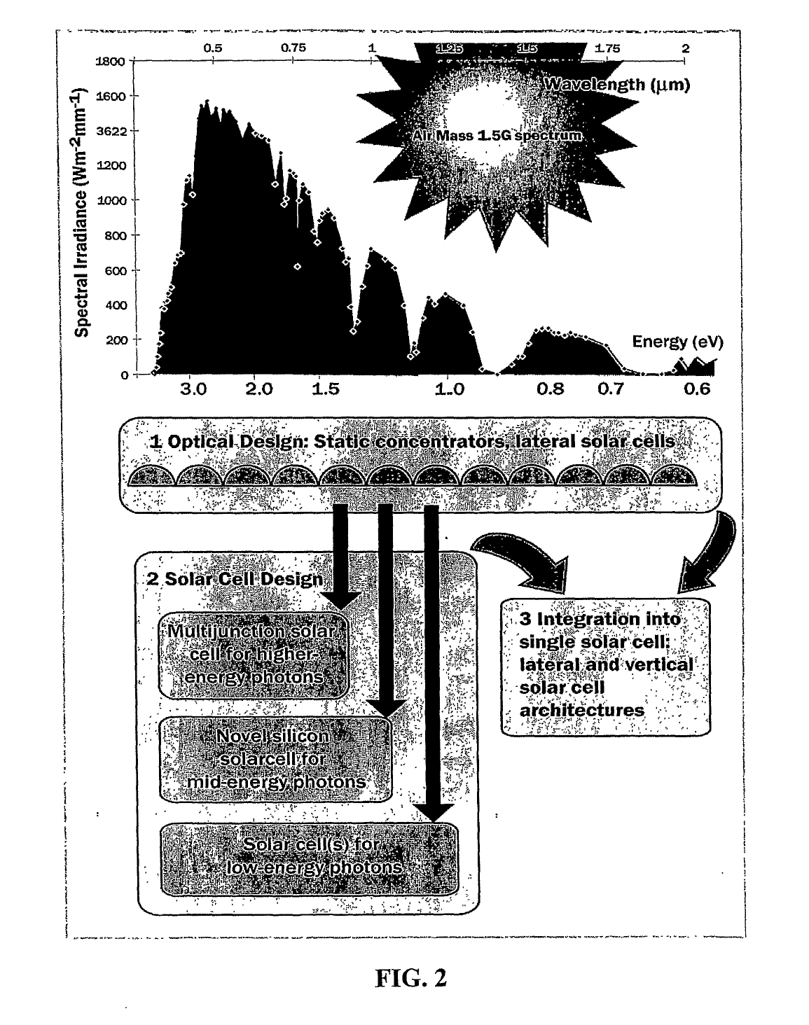

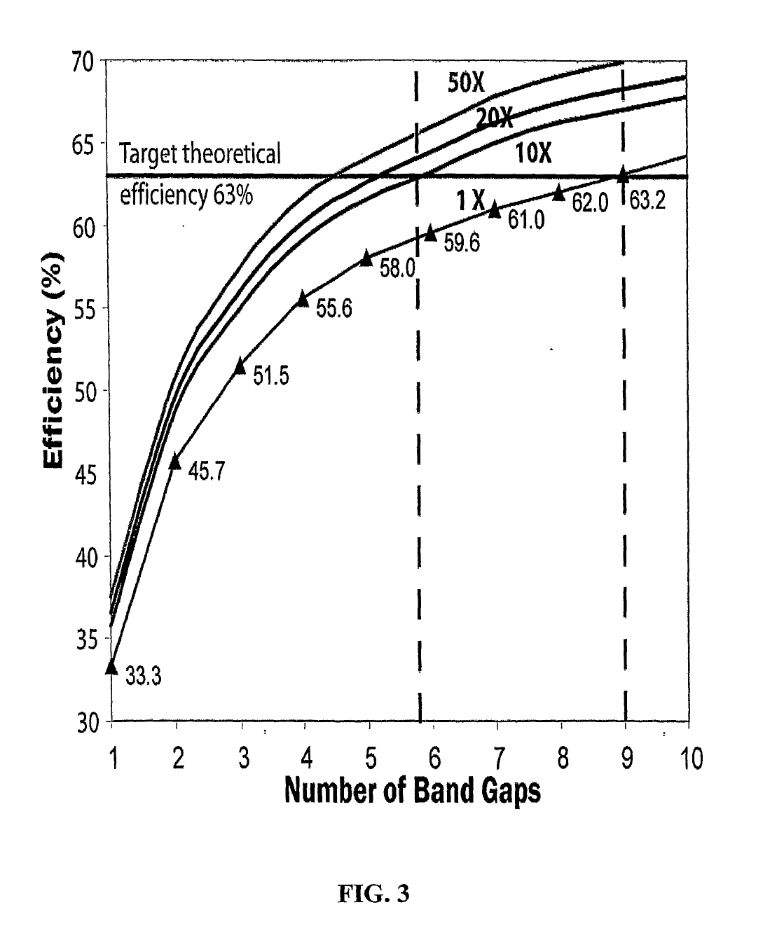

The integrated optical/solar cell device of the present invention allows efficiency improvements while retaining per area costs, and hence expands the applications for photovoltaics. FIG. 2 is an exemplary flow diagram showing the steps of (1) optical design; (2) solar cell design; and (3) Integration of the single solar cell into lateral/vertical architectures for solar cells. In addition, FIG. 3 is an exemplary plot of Efficiency as the number of band gaps for the Air Mass (AM) 1.5G spectrum varies by concentration.

In addition, the method of the present invention is a design approach that focuses first on performance, enabling the use of existing state-of-the-art photovoltaic technology to design high performance, low cost multiple junction III-Vs for the high and low energy photons and a new silicon solar cell for the mid-energy photons. Further, the present invention circumvents existing cost drivers through novel solar cell architectures and optical elements. Furthermore, the present invention utilizes the increased flexibility of the design space and provides two other III-V based solar cells, using III-nitrides or recently demonstrated In-rich III-V defect-tolerant materials.

Further the present invention addresses an even more ambitious goal—to decouple the efficiency/cost from that typical for semiconductor technologies and to move to a paradigm of solar cells as a coating (i.e., able to be applied in large areas at low cost). The realization of such a change depends not only on development of solar cell with new physical operating principles, but also new fabrication technologies. Recently, many low-cost new approaches, particularly based on new materials such as organics or nanostructures, have been proposed and these have demonstrated desirable optical or absorption properties. However, there are fundamental barriers to the implementation of such approaches to ultra-high efficiency, and the present invention addresses both the technological challenges of making low-cost nanostructures as well as the fundamental bathers to performance.

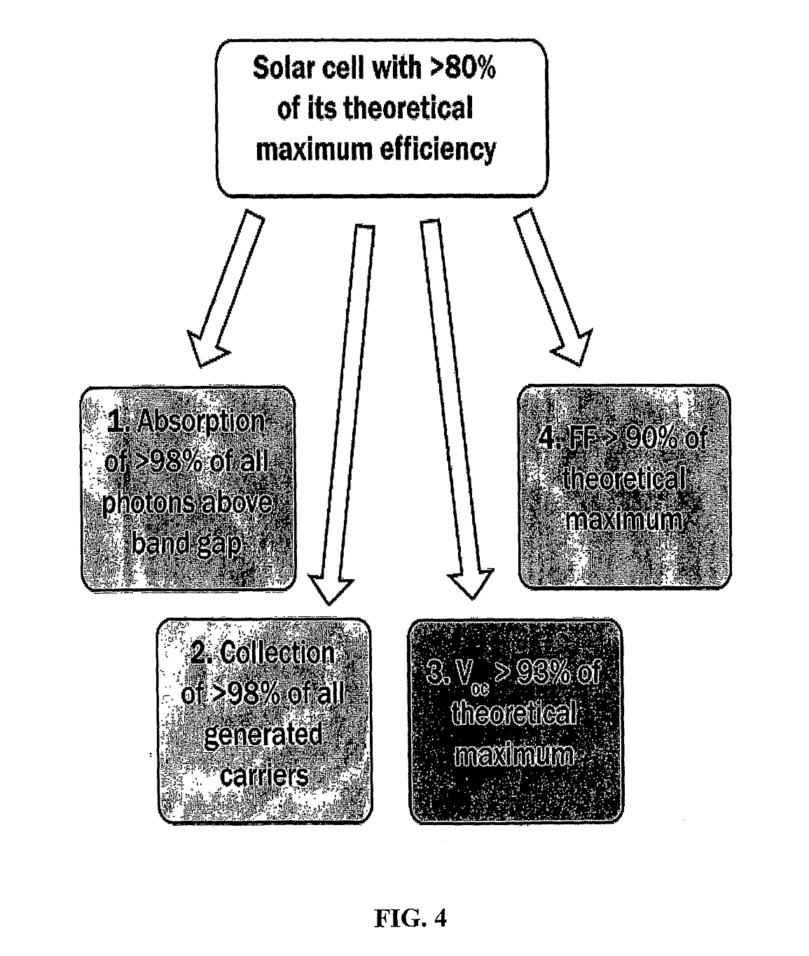

FIG. 4 is an exemplary diagram summarizing the requirements for >50% efficiency solar cells. In particular, the realization of >50% solar cells includes at least three factors: (1) thermodynamic efficiencies of 63%; (2) a solar cell which realizes >80% of its theoretical efficiency, and (3) a manufacturing approach leading to less than $1,000/m² with a pathway to $100/m² in mass production. These factors are discussed in more detail below.

The first criterion for a solar cell with over 50% real-world efficiency is that the ideal theoretical efficiency must be well over 50% under Air Mass (AM) 1.5G spectrum conditions to allow for unavoidable device losses not included in efficiency limit calculations. The best solar cells, which have been optimized for decades, reach ˜75-80% of their theoretical efficiency and therefore the theoretical efficiency must exceed the target efficiency (50%) by 25%, making the required thermodynamic efficiency 63%.

FIG. 3, as noted above, shows the efficiency calculated using detailed balance approaches as a function of the number of band gaps for the AM 1.5G spectrum, and shows that at one-sun conditions, 9 or 10 individual junctions (or 9-10 separate energy levels or exciton generation events if using new solar cell approaches) are needed. Several spectra are used for efficiency calculations, each giving marginally different efficiency values. We use the AM.15G spectrum since the application is terrestrial with low concentration.

Such a large number of materials are impractical for many reasons, including the availability of materials, cost, integration, and mismatch losses. Increasing the efficiency requires increasing the input power density via concentration or altering the solar spectrum. The method of the present invention avoid approaches which rely on altering the solar spectrum since the efficiency of such processes (phosphors, up/down conversion) are well below that required for high efficiency photovoltaics. However, the present invention comprises an integrated optical/solar cell design approach is ideally suited to utilize such effects if a breakthrough in this area occurs. To avoid tracking concentrators, which are primarily suited for large-scale applications, the present invention comprises static concentrators, which are deployed identically to a conventional module. In addition, FIG. 3 shows that 10 to 20-× concentration increases the efficiency for a given number of band gaps, and only 5-6 junctions rather than 9 or 10 are required.

In order to reach >50% efficiency, the solar cell must attain >80% of its theoretical efficiency of 63%. The efficiency of a solar cell is given by η=(I_{sc}V_{oc}FF)/Pᵢₙ, where I_{sc} is the short circuit current and depends on the absorption of light and the collection of light generated carriers, V_{oc} is the open circuit voltage and FF is the fill factor. To achieve >80% of the theoretical efficiency, all these must be as close as possible to their theoretical values, as shown in FIG. 4. High absorption and collection occurs for semiconductor-pn junctions when the absorption depth (1/α, where α is the absorption co-efficient) is less than both the device thickness and the minority carrier diffusion length. This is readily achieved with high quality material, since bulk materials with lower absorption coefficients also have higher minority carrier diffusion lengths. Even for defected materials, a pn junction solar cell has high collection with appropriate device design and parameters, such as light-trapping and drift field solar cells; for pn junctions, absorption and collection can be controlled by device design and optical elements. However, both absorption and collection are more difficult with nanostructured approaches and require additional optical elements and improved device designs to achieve high absorption and collection.

For both pn junction and other novel approaches, the central issue in achieving >80% of the theoretical efficiency is realizing a voltage which is >90% of its theoretical value, particularly when using realistic, possibly defected materials which have higher recombination, and reduced V_{oc}. The V_{oc} is generally set by the lowest quality, possibly localized region in the material, even though absorption and collection integrate over the entire junction. This is why only low-defect, single-crystal solar cell junctions have shown V_{oc}'s approaching their theoretical limit, and is one reason why approaches in which the absorber layer is not the same Material as that which collects/transports the charge (such as organic and dye-sensitized solar cells) do not perform near the theoretical efficiency limits imposed by the absorbing material. Both because the lowest possible theoretical recombination is achieved when the recombination is limited by radiative recombination in the absorber and also because in most configurations the transport materials are poor, such structures do not achieve a high fraction of their theoretical voltage. Thus, the central issue in achieving a high fraction of the theoretical efficiency is the material quality, not just of the absorber (if different from the transport material), but also of the collecting material.

The cost of solar cells can be divided into three primary drivers: 1) substrate, 2) epitaxial growth or junction formation, and 3) processing such as metallizations and antireflection coatings. The present invention minimizes the substrate cost by avoiding use of expensive III-V or silicon substrates, assembling the final solar cell on glass—a relatively inexpensive substrate. Although silicon wafers are used in the production process, these will not need to be electrically active, so can be low cost. Although the cost of epitaxial growth of III-V layers is currently very high, the high cost is primarily related to capital investment rather than raw material costs. These costs can be reduced by large scale manufacturing. A primary strategy for reducing costs of all three of these is to use concentration to reduce the semiconductor area.

The above discussion of the requirements to >50% efficiency solar cells shows that there are several central challenges in reaching very high performance solar cells. The first of these is the need for static concentrators. Previously, static concentrators have been proposed for existing solar cell modules, but the large cell size makes the optics too thick and too low concentration. The present invention circumvents this limitation by integrating the design of the static concentrator with the solar cell and interconnect technology, allowing high performance micro-concentrators which avoid the above-discussed issues and give higher concentration using thin optic elements.

A challenge in achieving >50% efficient solar cells is due to the numerous, competing constraints on material choice including: (1) constraints imposed by the need for specific band gaps to reach optimum efficiency; (2) band gap limitations imposed by series-connected, current-matched architectures; (3) lattice-matching constraints; (4) material compatibility constraints since the epitaxial growth of one layer must be compatible with all others (i.e., growth temperatures must not affect other layers, thermal expansion coefficients must be closely matched, inter-diffusion should be avoided, etc); (5) losses due to spectral mismatch; and (6) cost considerations.

The present invention realizes a solar cell which is close to its modeled limit and is simultaneously manufacturable on a large scale. The present invention the approaches described above to allow a robust solution to the central technical challenges: achieving high concentration without tracking and solving the materials/cost issues in implementing solar cells with >50% efficiency.

The present invention is an integrated optical and solar cell design, which dramatically increases the design space. By integrating the optical design with the solar cell design, a much broader choice of materials is permitted, allowing high efficiency, the removal of many existing cost drivers, and enabling the inclusion of multiple other innovations. The key optical element is a static concentrator, which is then used in either a lateral or a vertical architecture. To achieve compact and robust packaging, the optical concentrators of the present invention will be of a tiled nature, the design of which will depend on the co-optimization of the optics and cells to achieve maximum conversion efficiency.

A static concentrator increases the power density on the solar cell, but does not need tracking, and is deployed and used identically to a 1-sun solar module by using a wide acceptance-angle optical element (typically non-imaging), which accepts light from a large fraction of the sky. Unlike a tracking concentrator, a static concentrator is able to capture most of the diffuse light, which makes up ˜10% of the incident power in the solar spectrum. The trade-off for the wider acceptance angle is a lower concentration. In practice, high levels of concentration are achieved by rejecting the light from regions of the sky in which the power density is low throughout the year, allowing 10× concentration without tracking. Further, if the module position can be manually adjusted at any point in the year, the maximum concentration increases. Depending on how long the module is to remain in a fixed position, the concentration can range from 10×to 200×.

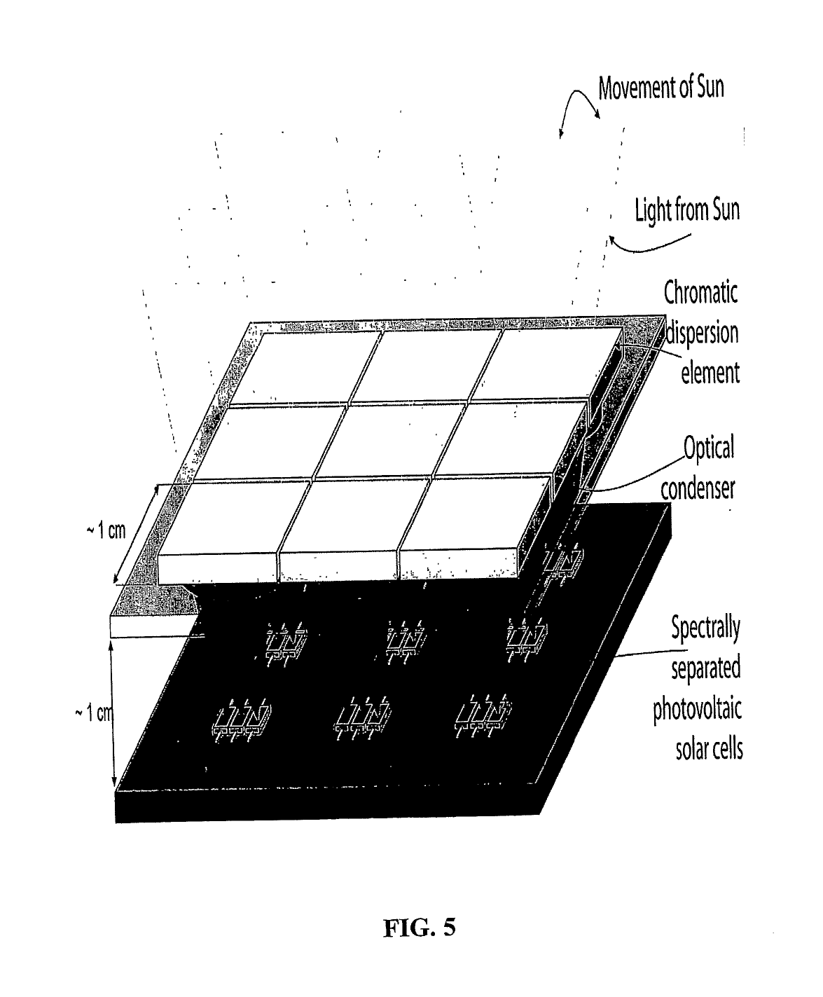

FIG. 5 illustrates how a static concentrator is augmented with sliding optical sheets—for tracking, and a dispersive element—for lateral energy collection. Tracking can be accomplished by employing adjacent sheets of low-cost planar optics, which will be integrated into the basic tiled structure of the solar cell. As the sun moves, shifting a sheet a fraction of a millimeter in X and Y by a piezo-tractor at a corner of the solar module can provide a simple and low-cost tracking mechanism that assures that the position and angle of the image of the sun match with those of the dispersive element independent of the sun positions. A single low-cost, low-power DSP circuit handles all sense, control, servo, and actuation logic for all solar cells in a system. In operation, feedback signals indicating solar cell efficiency will be exploited in a servo loop to adjust the position of the movable sheet(s).

In order to implement the lateral solar cell without tracking, the movement of the sun across the sky must be accounted for. The concentrator with micro-trackers allows alignment of the solar beam to the spectral splitter. The higher number of spectral regions or bins into which the spectrum is divided is determined by the optical design, with losses increasing as the number of spectral bins increases due to steering the sunlight onto the “wrong” solar cell. To circumvent this, a smaller number of individual solar cells, each consisting of 2 or 3 stacks, can be used. The solar cell device designs of the present invention focus on dividing the light into three regions or bins—high energy, mid-energy and low energy.

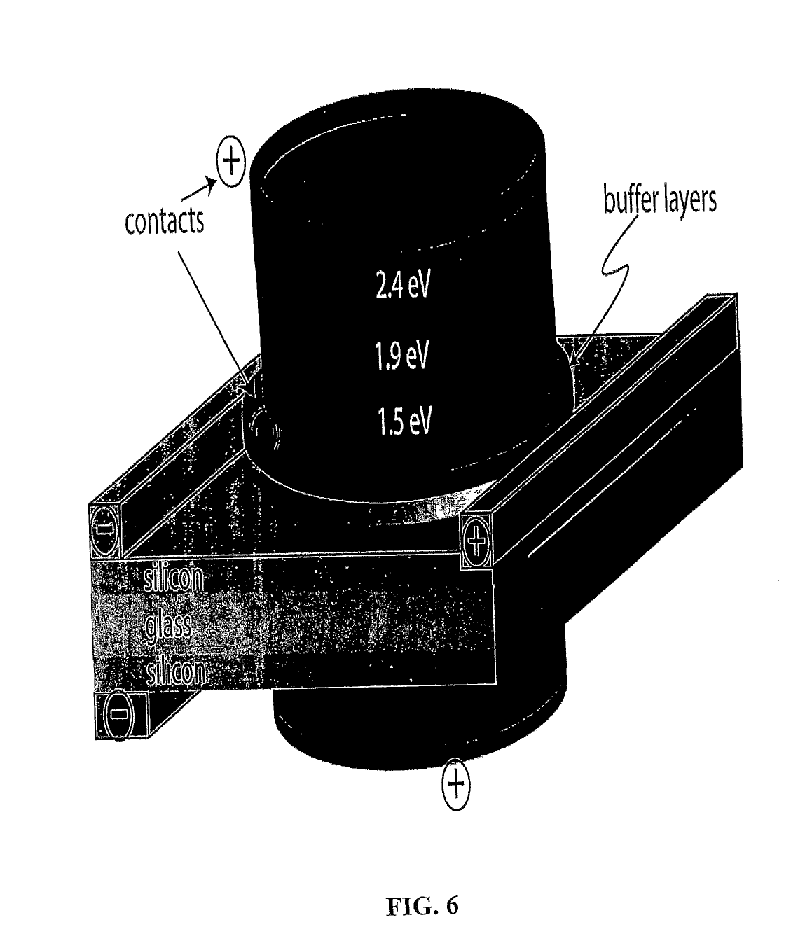

A parallel approach to the lateral architecture discussed above is a vertically-integrated device in which the solar cells can be independently contacted, as shown in FIG. 6. Note the variety of contact schemes and shorting junctions possible. This approach is enabled due to the inclusion of static concentrators, which leave the majority of the surface area without an active solar cell, thus leaving room for separate contact formation to individual junctions. The independently-connected vertical architecture realizes similar benefits as a lateral solar cell architecture in minimizing spectral mismatch, increasing flexibility of material choices and avoiding tunnel contacts. Depending on the integration process, this approach may also avoid lattice matching by using layer transfer.

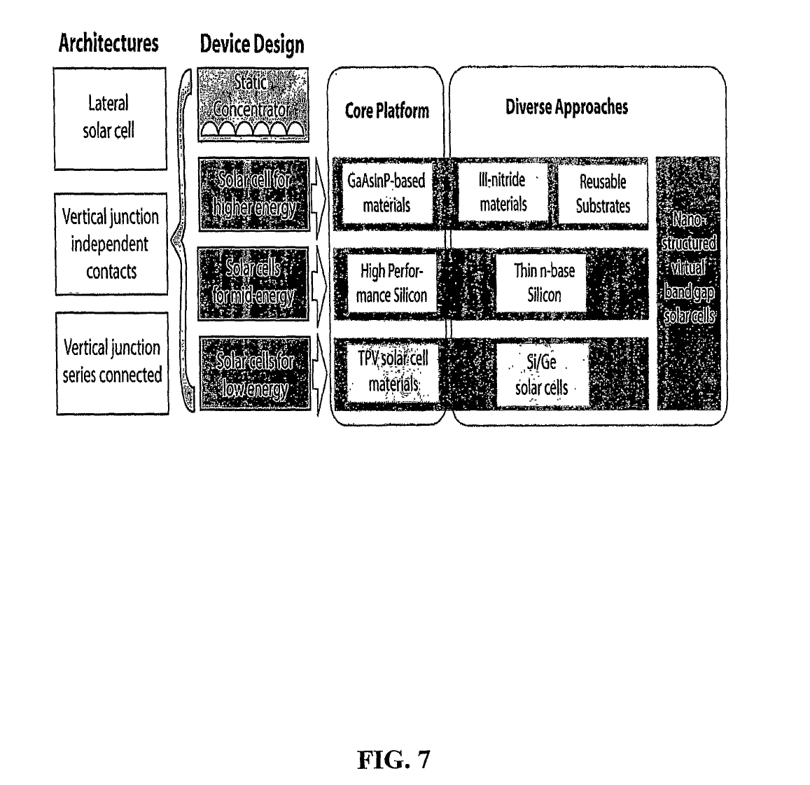

The present invention chooses among the expanded design space allowed by the optical elements to first design for performance, eliminating only those aspects of high performance that are fundamentally incompatible with ultimately achieving low cost, and then designs for low cost manufacture. The method of the present invention involves parallel approaches in the initial phases, such that success in no case depends on a single high risk approach. The architecture/device approaches are shown in the flow diagram of FIG. 7.

The design emphasis in the method of the present invention is on high performance leads to a core approach based on developing a multiple junction solar cell using the materials which have demonstrated the highest performance for the wavelength range close to their band gap, giving different materials for the high, mid- and low-energy photons. The highest performance materials are ternary compounds from the GaInAsP materials system for high-energy photons, silicon for the mid-energy photons, and InGaAs or other thermophotovoltaic (TPV) materials for the low energy photons.

The second design method constraint is to ensure that materials and approaches are consistent with large scale manufacturing and low cost. This drives the core approaches to reduce substrate, fabrication, and integration costs. Since, as abundantly shown by the IC industry, large scale fabrication benefits from a monolithic approach, low integration costs are achieved by a monolithic structure and low material costs are achieved through use of a silicon substrate, the lowest manufacturability risk consists of direct growth on silicon, which gives low substrate and integration costs.

While the method of the present invention offers a high probability of success, we recognize that other material systems and approaches have unique advantages. The parallel approaches of the method of the present invention may supersede a core approach either due to improved performance, or equivalent performance at reduced cost. These approaches include other materials for a multiple junction solar cell, such as the III-nitride material system, new device structures using In-rich defect tolerant III-V materials for the high energy photons, and the Si/Ge materials system for low energy photons.

Alternatively, a different method of the present invention, with a high technical risk but also a high pay-off, is to develop nanostructured virtual band gap solar cells, using either multiple exciton generation or multiple energy level (intermediate band) solar cells, in conjunction with self-assembled fabrication technologies. In practice, all of the designs and technologies are inter-related. For example, the nanostructured virtual band-gap solar cells are optimally suited and closest to realization as a low-energy converter and the final solar cell could be a hybrid between the nanostructured and multiple junction approaches. Each of these photovoltaic concepts are described in more detail in the following sections.

High performance, low cost III-V materials cells for high energy photons are further discussed in the following. Multiple junction solar cells (also called tandems) consist of multiple pn junctions, each converting a narrow range of the solar spectrum. Three junction (3J) multiple junction solar cells represent the existing state-of-the-art, with efficiencies of 37.3% at 175× and a recently confirmed result of 37.9% at 10×.

Incremental methods based on existing 3J approaches face several fundamental challenges, including the inherent cost of incorporating III-V or Ge in the final solar cell, increasing lattice matching constraints for higher band gaps and lack of choice in high band gap materials, lack of ideal materials in the mid- and low energy range, particularly if Ge is not used as an active solar cell. Overall, the challenges can be summarized as simultaneously (1) developing ideal pn junctions in an additional 3 to 4 materials and (2) reducing costs of the existing tandems by a factor 100 or more.

In addition, there are multiple concentrator/solar cell combinations which can be implemented to reach >50%. 4J solar cells require concentration of >150×, and 7J solar cells require >5×. The present invention comprises a 5-7J solar cell with silicon as the mid-energy converter, with 3J on top of silicon and 1-3J below silicon, since the 4J solar cell relies on success in the high concentration internally-tracking static concentrator. The number of junctions between 5 and 7 depends on the low energy converter, since optimum designs include 3J above silicon, and one, two or three junctions below Si. Since the low-band gap device is separately grown and/or attached to the silicon substrates, the high, mid and low energy devices can be considered separately.

The use of Si reduces the cost and high band gap problems, and using Si/Ge for the low energy photons increases the band gaps for the low-energy devices. This approach offers considerable flexibility and high probability of success. Even assuming that we implement only a 5J solar cell (rather than 7J) and that the optimization of the junctions is not fully realized (thus allowing us to achieve only 50% of the theoretical efficiency for the low energy and 75% of the theoretical efficiency for all solar cells); the overall efficiency at 20× is 45.1%. Achieving 6J with 75% of the theoretical efficiency for the three lowest band gap junctions and 85% for the higher band gaps, we achieve 53.7% at 20×.

The advantages of using silicon as a substrate for III-V materials, particularly for integration of GaAs, have long been recognized and have prompted numerous efforts to develop this technology for optical devices, integrated circuits and for photovoltaics, but have consistently encountered poor material quality. The integrated optical/solar cell approach allows the present invention to circumvent this for several reasons as discussed below.

First, the flexibility in band gaps is substantially increased, and thus we can choose materials in which the lattice-matching and current matching constraints are not severe. For example, in a 6J solar cell, fixing the band gap of the third junction to that of silicon, limiting the top band gap to less than 2 2 eV and raising the lowest energy gap to 0.7 eV alters the efficiency by less than 1% relative.

Second, by using low levels of concentration, devices can tolerate higher dislocation densities since non-ideal recombination components become less significant at higher bias. This was experimentally demonstrated recently in that the record solar cell that contained a metamorphic low band gap solar cell, improved by a greater fraction under low concentration (10×) than can be accounted for simply by increased power density, and also by another recent report of tandems at low concentration.

The method of the present invention utilizes multiple parallel approaches for the high photon energy conversion, since the top three junctions generate 66% of the total power of a 6J solar cell, with the focus of the approaches on achieving high quality growth on silicon through a combination of new solar cell design, new materials systems, and advances in buffer layer growth.

The highest performance solar cells use Ge or III-V substrates and ternary materials from the GaInAsP material system. To circumvent the traditional performance and cost drivers, the present invention comprises growing a 3J solar cell on low-cost silicon. The lowest risk approach is to grow an “inverted” solar cell on Si, such that the highest band solar cell is grown on Si, and then grade the remaining devices to higher lattice constants and lower band gaps. The enabling feature of this approach is to extend the approach of recently demonstrated high quality step-graded buffer layers to allow high quality growth on Si substrates. The lattice mismatch for the Si/high band gap solar cell is similar to the lattice mismatch for existing high performance tandem solar cells, giving a high probability of success.

Further, this approach is low cost since the silicon substrate can be a sacrificial substrate since electrically poor but crystalographically high quality wafers are very low cost. Further the use of a sacrificial wafer layer overcomes the existing barriers to making layer transfer manufacturable at a large scale and low cost. By thinning the individual layers and further optimizing the buffer compositions, including the use of Al-containing grades, we can extend this approach to direct growth of a cell on an active Si solar cell, allowing a low-cost, high performance monolithic solar cell on Si.

The III-nitride material system has several features which allow both high performance multi-junction solar cells and low cost: an ideal band gap range; good lattice matching to <111> Si compared to sapphire (which is currently used); existing industry centered around the nitrides; high radiative efficiency even with high dislocation densities; high mobilities, allowing good collection from defected materials; a large piezoelectric constant, allowing control of surface recombination; and the availability of high band gap materials, allowing device designs with direct band gaps above 2.2 eV. Such high band gaps are not available in other established material systems, but are desirable since they are needed for multiple junction solar cells with a large number of cells.

Coupled with these advantages are also substantial challenges, including the undeveloped state of the low band gap, In-rich InGaN material system (particularly in achieving p-type conduction in realistic devices), the cost of the sapphire substrate, and the low minority carrier lifetimes. Using Si as a substrate avoids the cost of sapphire, provides improved lattice matching compared to the sapphire for the band gaps proposed, and has already demonstrated compatibility with GaN, despite the large mismatch in thermal expansion coefficient. Further, the use of silicon avoids the issues with InN, since the lowest band gap required is above 1.5 eV. We have already demonstrated high collection and voltages in GaN and InGaN solar cells, and identified that control over internal electric fields is a critical design parameter. By utilizing a new dopant technology for InGaN developed at Georgia Institute of Technology and a device design which includes the impact of the piezoelectric effects, the present invention can achieve high performance InGaN solar cells.

The present invention leverages the cost/performance benefits of existing solar cell technology to achieve both high performance and low risk. While laboratory silicon solar cells have demonstrated high performance, a central technical challenge is to incorporate the high performance features in a low cost solar cell. To exploit the potential of silicon as a low cost, high performance photovoltaic material. The present invention is a novel solar cell grown on glass, enabled by several innovations in solar cell design, including the move to thinner silicon junctions, passivation of the Si surface by means other than insulators, the use of an optically transparent substrate, and recently demonstrated high minority carrier lifetimes in n-type silicon. To mitigate the risk associated with moving to such an ultra-low cost approach, the present invention utilizes parallel approaches.

The present invention also utilizes recent advances in surface passivation using deposited coatings, and proposed innovations in light trapping (described in nanostructured materials) to realize high performance, but on silicon wafers rather than glass. The present invention also comprises an approach to the fabrication of crystalline silicon solar cells with the deposition of wide-band gap semiconductors to passivate the surfaces and achieve higher voltages and efficiencies.

A fundamental challenge in ultra-high efficiency multiple junction solar cells is the efficient conversion of low energy photons. This is not just a material problem (although there are material issues), but rather an inherent problem that is also encountered in direct thermal conversion via photovoltaic approaches. Efficiency limit calculations assume the recombination is radiatively limited and that the quasi-Fermi level can be made arbitrarily close to the conduction and valence band edges. Record-efficiency solar cells, both Si and III-V tandems, typically achieve V_{oc}'s within 0.1 eV of the radiative limit. Since the radiative limit varies relatively slowly, a convenient equation is V_{oc}≈q(E_{g}−0.4 eV). For large band gap solar cells, the 0.4 eV offset is a small fraction of the overall voltage, but for smaller band gaps, it becomes a dominant effect. To maintain the highest possible voltage, the present invention uses the highest performance low band gap materials, those developed for thermophotovoltaic devices, coupled with minimization of recombination volume in the low band gap materials by using heterostructures and light trapping.

A second critical limitation is the difficulty of incorporating low band gap solar cells with existing devices, due to the large lattice mismatch with conventional substrates. Layer transfer allows the use of existing TPV solar cells, but a lower cost approach is to grow Si/Ge solar cells on the rear of the silicon wafer, incorporating new approaches to light trapping in order to increase absorption. As a parallel approach to circumventing the low V_{oc}'s in low band gap materials, the present invention uses virtual band gap solar cells, as described below.

Nanostructured virtual band gap solar cells and photonic crystals are further discussed below. The transformative potential of nano-structured PV arises from two distinct properties: First, the ability of nano-structures to alter and control critical material parameters and second, the potential to implement nanostructured materials not by epitaxial growth processes, but by lower cost, novel self-assembly processes, thus allowing the “ultimate” paradigm shift long-sought in photovoltaics, a cost model which follows coatings, but an efficiency model which follows semiconductors. The control of the material properties via nanostructures means that a single nanostructured solar cell can theoretically exceed the efficiency of a single pn junction solar cell by using virtual band gap solar cells, in which a photon may be efficiently converted without requiring a “physical” band gap at or near that energy. This provides the further benefit that nanostructured virtual band gap solar cells can be used to overcome the low voltage encountered by low-band gap pn junction approaches and further opens the material design space.

Two physical mechanisms can be used in virtual band gap solar cells; multiple exciton generation and multiple energy level solar cells. Both of these approaches rely on nanostructures for their implementation, and the present invention uses further innovations which allow a practical, low-cost nanostructure device through the formation of ordered quantum dot arrays and new device architectures for contacting the arrays.

TABLE 1
Band gaps and material options for 6J solar cell

| | Proven III-Vs | | Defect |
|---|---|---|---|
| High Energy | materials | III-nitrides | Tolerant |
| 2.1-2.44 eV | GaInP/AlGaInP | InGaN | |
| 1.8-1.95 eV | GaInP/GaAsP | InGaN | InGaP |
| 1.4-1.55 eV | GaAsP | InGaN | InGaP |

| Mid Energy | Silicon solar cell | |
|---|---|---|
| 1.12 eV | Silicon substrate | Thin n/p on glass |

| Low Energy | TPV materials | Si/Ge alloys |
|---|---|---|
| 0.9-0.95 eV | InGaAs | Si/Ge |
| 0.5 eV, 0.7 eV | InGaAs | Ge |

The method of the present invention optical effort comprises the design and development of two optical elements: a static concentrator and the optics for lateral solar cells. The fundamental novelty in these approaches is the incorporation of these optical elements as integral parts of the solar cell assembly. The integration for the concentrator and lateral optics will preferably take place at the very last fabrication step in which the optical element arrays are attached to the solar cell chip package (e.g., as a simple “snap-on” assembly step). The process technologies for the optical approaches for the candidate concentrator and lateral optics include, but are not limited to a range of batch-producible refractive, reflective, and diffractive technologies.

The method of the present invention will also comprise analyzing candidate approaches theoretically and experimentally for manufacturability; cost of development, production, assembly, alignment, and maintenance; tolerances; temperature sensitivities; stability & reliability; and performance. Analysis of trade-offs in the performance of the optical elements will focus on such issues as radiometric losses (from absorption, scattering, and reflection); reversible or permanent environmental or aging effects (from temperature, humidity, dust, scratches, and similar effects); and non-idealities in the optical collection (e.g., due to optical aberrations that could cause the delivery of a portion of the photons to the “wrong” junction)

Technology II, III-V multiple junction solar cell is discussed below. The central enabling process technology to the realization of >50% efficient multiple junction solar cells is the development of a manufacturable approach to incorporating III-V layers which allows a high performance solar cell with a low-cost substrate and solar cell, primarily silicon. Table 1 above shows an overview of approaches used in the present invention.

The record efficiencies obtained for existing tandem solar cells using ternary materials from the GaInAsP material system demonstrate the suitability of these materials for very high efficiency PV devices. The central challenge in realizing new 3J solar cells using these materials is to develop approaches that allow integration of the 3J with an active silicon wafer, and develop approaches for the higher band gap solar cells, which is at the upper limit of using the GaInAsP material system.

The ultimate goal of directly growing a 3J stack with band gaps of nominally 1.5 eV, 1.8 eV and 2.2 eV on silicon. Device modeling using realistic material parameters show the ability of this structure to reach 50%. Device simulations using ideal, GaInAsP-like materials predict an achievable efficiency of 39.5% for a three junction high energy stack under 10× concentration overall the entire solar spectrum. Using PC1D, the most commonly used pn junction simulator in photovoltaics, for the Si middle solar cell and for the bottom cells gives an overall efficiency of 15.4% over the entire solar spectrum. Combining these efficiencies gives an overall efficiency of 59.7% compared to theoretical efficiency of 63.2%. Previous record efficiencies have reached 90% of similar simulation results, indicating that well-optimized devices can reach 85% of the theoretical efficiency, which supports our model and indicates that the overall solar cell can achieve >50%.

The present invention comprises a development path to a high performance solar cell on silicon follows an initial approach of growing on III-V (GaAs) substrates in order to examine and optimize material and growth parameters for the different material compositions. By growing an etch-stop layer and growing in an inverted configuration (i.e., with the highest band gap material as the first solar cell), the layers can be transferred to the Si substrate, and the wafer removed. The feasibility of this approach was demonstrated by the record efficiency of 37.9% at 10× achieved for an inverted GaInP/GaAs/GaInAs cell. Initial growth on GaAs will provide a convenient way to demonstrate and study aspects of the inverted structures. GaAs-based 3J, high band gap structures would also be useful if the GaAs substrates could be reused. Although reuse may be possible, substantial advantages are gained by growing on Si, and hence the present invention does not rely on substrate reuse as our preferred path to large-scale manufacturability.

The next step in the method of the present invention for the developmental path is to grow an inverted solar cell structure on a low-cost, electrically inert but high crystalline quality silicon substrate. While this approach is also primarily intended as a developmental path to direct growth on Si, it mitigates risk as the Si substrate can be low enough cost to be a sacrificial substrate. Although III-V growth on silicon has experienced limited success in the past, the present invention will be using new approaches that have recently been developed such as nucleation of high-quality, coherent (instead of the relaxed structures studied in the past) III-V growth on Si which has been demonstrated recently using a GaAsN alloy lattice matched to Si. Alternatively, a Si—Ge grade may be used to adjust the lattice constant before nucleating coherent lattice-matched GaInP The carefully optimized grade demonstrated by the 37.9% efficiency relieved more strain than will be needed for each of the grades in the structure of the present invention. None of the studies on silicon so far have used an inverted approach. The final step in the development of the 3J stack directly on Si is to thin the buffer/active layers developed in the inverted solar cell structure, such that a low defect density template can be achieved for the 1.5 eV device on Si, and the two higher band gaps are grown on this device.

The III-nitride system has undergone rapid development due to its use for white/blue LEDs. The demonstration of the band gap of InN as 0.68 eV rather than the previous 1.9 eV makes this an ideal candidate for solar cells since the InGaN materials can be used to implement band gaps below the previously assumed limit of 1.9 eV. Since the present invention includes growth on Si, the numerous material issues associated with the low-band gap In-rich nitrides is avoided. Thus, the central challenges in implementing a high efficiency InGaN solar cell on silicon are the low minority carrier lifetimes and the development of buffer layers for growth on Si.

Both experimental and simulation evidence exists that the minority carrier lifetimes allow high efficiency solar cells. The present invention uses three junctions at 20×, these results show that, primarily due to the very high absorption coefficient of the nitrides and the ability to maintain high electric fields, the internal quantum efficiency remains over 98% over the entire spectral range and that the model voltages achieve the characteristic V_{oc}=q (Eg−0.4 eV) expected from a high quality solar cell, even with the low lifetimes measured in existing GaN material, thus meeting the criteria for >50% solar cells. Further, our experimental results for un-optimized initial devices with high parasitic absorption in the contacting layers have achieved over 60% internal quantum efficiencies in GaN solar cells. In addition, for devices with light emission and photoluminescence at 2.4 eV, the present invention has achieved voltages of 2V.

Additional confidence for the high efficiency potential of the InGaN systems arises from other advantageous material properties of the nitrides, such as the high piezoelectric constant and polarization effects which can be used to develop new solar cell approaches and which mitigate the risks associated with proposing a relatively new material system. Additional risk mitigation approaches, such as growth on Ge or other substrates and using layer transfer, and device designs and growth approaches which reduce the issues with p-type doping.

The developmental path focuses on two parallel paths. First, solar cell architectures and materials will be grown and characterized on sapphire to identify and solve device-design related issues and to optimize material growth conditions. The central novel device issues include maintaining a high electric field in the p-i-n solar cell structure via optimization of growth conditions and by utilizing the piezoelectric characteristics of the nitrides, by demonstrating low surface recombination velocity, and by optimizing doping conditions. The 1.5 eV and 1.9 eV devices will be grown via MBE, and the higher band gap will be grown by MOCVD. In parallel, the second central issue to be experimentally optimized is the development of the buffer layer for growth on Si. While silicon has a closer lattice constant for the proposed InGaN compositions, the thermal expansion coefficient of Si is substantially different from that of InGaN, and hence requires optimization of the buffer layer growth conditions and composition (which includes alloys with the AlN material system). Existing demonstrations of large area, crack free, low dislocation density films on silicon demonstrate the viability of buffer layer optimization. The later stages of the development plan involve the combination of the buffer layer and device structures into low cost, high performance solar cell, and evaluation of the manufacturability and cost of the two growth technologies to decide which is most suited for technology transfer and large scale production.

Analysis indicates that a practical silicon solar cell with and a one sun efficiency of 22% can be achieved. When incorporated in with the stack this leads to >50% efficiency. based on the first generation design. This novel design capitalizes on the minority carrier lifetime tolerance of impurities and defects of n-type silicon. The design also uses the relative ease of passivating n-type surfaces. Solar cell materials costs will be reduced by more than 80% compared to wafer-based silicon solar cells. Moreover, this approach allows open circuit voltages higher than those demonstrated from existing solar cells. The project to develop high efficiency, low-cost silicon device is made low-risk through the collaboration of the University of Delaware, the University of New South Wales, BP Solar, and Blue Square. This team represents a collaboration of leading experts in Si solar cells.

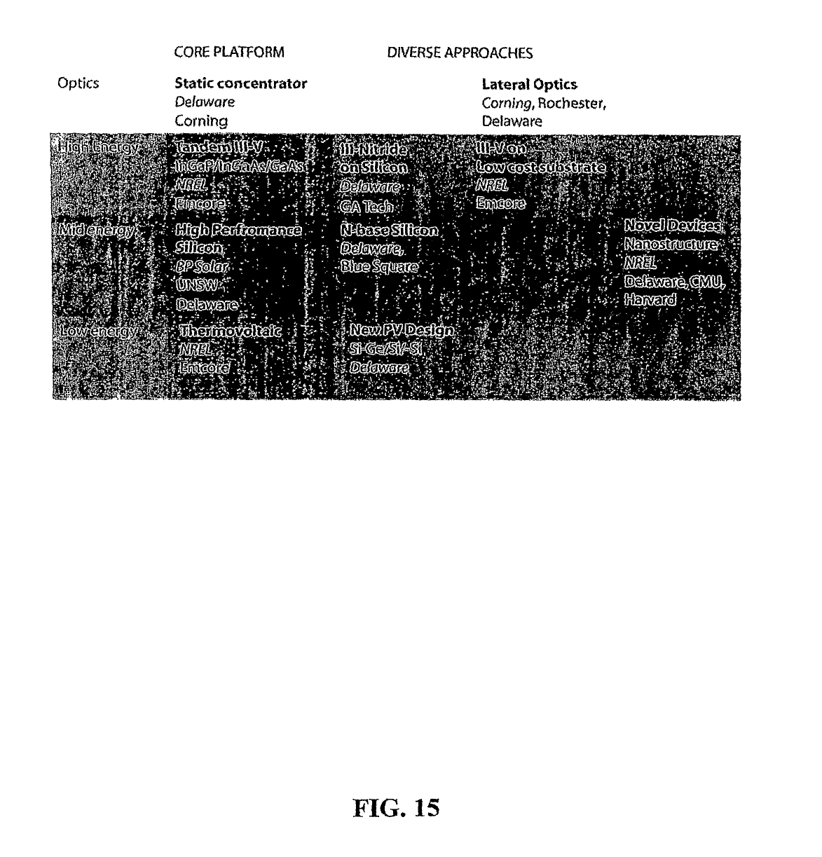

As shown in FIG. 15, in a thin solar cell, high efficiency can be achieved with reduced minority carrier lifetime due to a combination of reduced recombination volume and high carrier collection. Even for minority carrier lifetimes of 10 μsec, the efficiency of the thin device can be above 21%. Lifetimes of 100 μsec have been demonstrated on lower quality material and will be the target value.

A rear-junction solar cell is highly sensitive to the value of front surface recombination, and hence the front surface of a rear junction device must be well-passivated. However, the n-type front surface takes advantage of the fact that n-type silicon can be more readily passivated, and hence the efficiency limit imposed by front surface recombination remains above 22% for devices <20 μm thick in which the lifetime is 100 μs. A further advantage of rear-junction devices is that they are not highly sensitive to rear surface recombination velocity, such that even for very thin devices, a rear surface recombination velocity of 1,000 cm/sec introduces an essentially negligible effect for devices between 20 and 50 μm thick. These advantages mean that even with the inclusion of losses in optical confinement amounting to 20% of the light escaping from the surfaces, efficiencies above 22% can still be achieved for devices ranging from 10 to 50 μm thick.

The solar device design is a significant departure from existing thin silicon designs. In particular, this thin silicon solar cell will be designed to achieve very high voltage. Following is a description of the structure.

The substrate is made from glass that is thermal coefficient matched to the silicon over the temperature range of 700 to 1000 C. The substrate is coated with P+ silicon, which is re-crystallized to form grains larger than 1 mm. The P+ silicon on glass receives a coating that functions as an impurity diffusion barrier, a selective wavelength optical reflector, and a passivation layer for the absorber layer that will be deposited on top of it. Openings are made through the barrier, optical, and passivation layers. For example: 10 micron openings (round) on 100 micron centers. The openings are close enough that carriers are collected before they recombine. The silicon photon absorber is N-type. The absorber layer can be deposited by CVD and then re-crystallized using standard techniques. The thickness of the absorber layer is between 20 and 50 microns for this application. There are several effective low cost ways to deposit this absorber in addition to the CVD. Top surface passivation can be a floating junction or a high performance, high temperature heteroface such as GaP or GaAsP.

Furthermore, thin solar cells with good surface passivation have higher voltages than conventional thick devices, even with completely ideal materials, since the recombination volume decreases. Traditionally, surface passivation has been based primarily on physical passivation of defects. However, recent results indicate that passivation can be achieved by using coatings or treatments which alter the surface structure. This approach allows a new, general class of surface passivation to be developed, rather than one which requires highly material specific information, and optimization on every different material. Overall, the high levels of light trapping and good surface passivation not only mitigate non-idealities, but allows us to more closely approximate the theoretical voltage limits on already well-optimized devices, and achieve high efficiencies in a practical solar cell.

The present invention uses existing state-of-the-art low band gap devices designed for thermophotovoltaic (TPV) applications, and uses layer transfer and substrate re-use to integrate them with the silicon solar cell. To further increase the efficiency and reduce manufacturability risks associated with layer transfer, the present invention uses new Si/Ge solar cell designs which allow us to directly grow on the rear of the solar cell. Further, the present invention uses two options for high V_{oc} low band gap devices, both of which rely on light trapping. By reducing the thickness of the device while retaining the same absorption through light trapping, the overall recombination is reduced, and hence the voltage increases. This approach requires low surface recombination velocities, which can be achieved in both the proposed InAs and also Si/Ge material system.

The second approach focuses on using quantum wells (or other nanostructures which can be incorporated into the device structure) in order to modify the effective band gap in the intrinsic region. This approach does not seek a thermodynamic efficiency increase from the inclusion of nanostructures, and hence the uncertainty and risk which exists for the other nanostructured devices do not apply here. Previous QW solar cell structures using this approach have shown that for QW solar cells, Voc is higher than a similar device with a physical band gap and has also shown high collection probabilities. The reduced absorption associated with nanostructured materials is circumvented by light trapping.

The method of the present invention comprises a developmental plan for using TPV materials first involves demonstration and optimization of two-junction stacks in the InGaAs material system on InP, and then demonstration of layer transfer of these structures to a silicon substrate. The developmental plan for the Si/Ge solar cell involves developing and optimizing 0.9 eV solar cells, and integrating light trapping to achieve high absorption and voltages. The growth of a Ge solar cell on this 0.9 eV Si/Ge solar cell allows a 2J stack directly grown on Si.

The potential for nanostructures to achieve high efficiency in photovoltaics remains controversial. Promising results have been reported using optically-based measurements, including the tailoring of the effective band gap, efficient luminescence or new absorption processes such as multiple exciton generation, and further point to the advantageous use of nanostructures in light emitters and detectors. Detractors point out that even using MBE-grown structures, the efficiency of nanostructured solar cells is uniformly lower than devices without the nanostructure, that demonstrated advances focus on absorption/emission, and devices do not even achieve a fraction of the absorption (the easiest solar cell parameter to control), much less the collection, voltage, and FF of existing semiconductor devices. Modeling and experimental work indicates that both are correct—existing demonstrations contain inherent flaws by ignoring fundamental issues which exclude the use of certain nanostructure configurations and materials, preventing even theoretical improvements of solar cell performance, despite the fact that these existing demonstrations are vitally important to demonstrate key physical mechanisms.

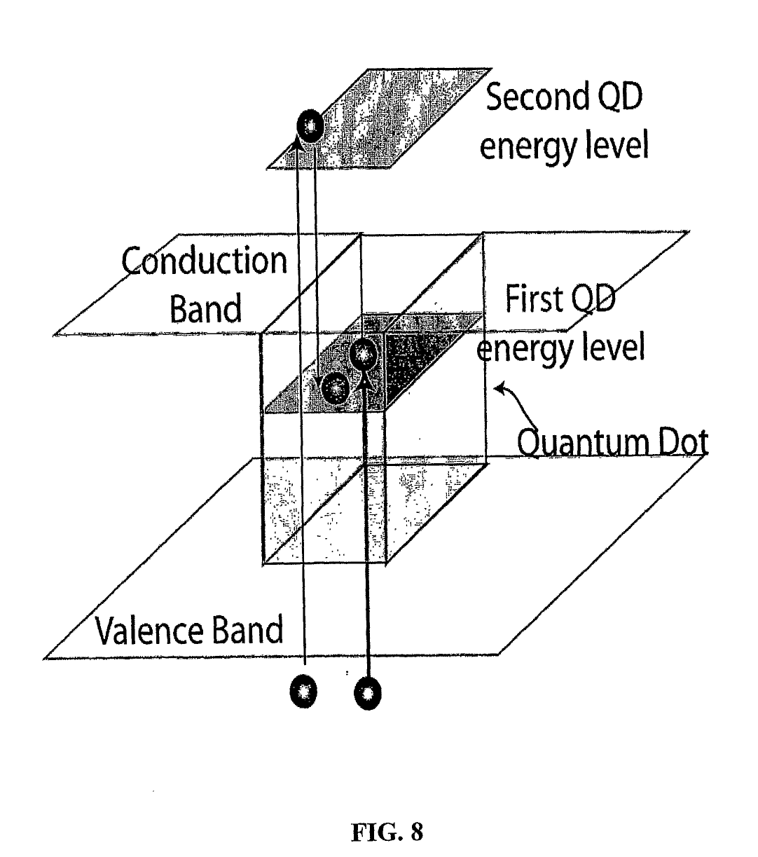

The present invention comprises multiple exciton generation MEG and multiple energy level (MEL) solar cells (of which the intermediate band is a specific case), since only these have demonstrated that the required physical mechanisms occur at a level consistent with high efficiency solar cells. In (MEG) solar cells, a high energy photon generates multiple excitons as shown in FIG. 8. In MEL solar cells, a low-energy photon excites a carrier to the middle energy level, and then another photon excites carriers from the middle energy level to the highest energy level as shown in FIG. 8.

The key challenge in nanostructured solar cell relates to transport of carriers. While the inherent confining potentials in nanostructures allow tailoring of material properties, they also introduce a barrier to transport of carriers at the low energy levels in the nanostructure. LEDs and lasers avoid this problem since they require carrier injection into, not collection from, the nanostructures. There are two fundamental solutions to the transport problem: (1) use of closely space nanostructured arrays which promote the formation of min-bands as shown in FIG. 8 and in which the miniband transports carriers; or (2) excitation of the carriers in the confining potential to the conduction/valence band of the barrier or matrix material (either thermally, via an electric field, or via photon-induced transitions), which then acts to transport carriers.

The use of closely spaced nanostructure arrays to solve the transport problem introduces several limitations. Only QD closely spaced arrays have a zero density of states between the bands. In other nanostructured arrays, carriers quickly thermalize to the lowest energy level. In intermediate band solar cells (a MEL solar cell which uses minibands for transport), carriers must be extracted at the upper energy level, and the thermalization represents a large loss mechanism, even in nanostructured materials which display slowed cooling rates. Further, using MEG in nanostructures other than QD arrays is also high risk since only QDs have demonstrated high rates of multiple exciton generation. Thus, for a solar cell using mini-bands, only QD arrays will give an efficiency increase.

However, mini-band approaches contain two key challenges. Closely spaced arrays of QDs with long range order are difficult to fabricate, particularly in a low-cost fashion, but unless the QD array is ordered such that mini-bands form, the solar cell will be dominated by the properties of the matrix or barrier material. Further, a metal cannot be directly used to contact the mini-band device, since this would “short” together two of the mini-bands. In nanostructures grown in conventional semiconductors, thin bulk regions of semiconductors can be used in between the metal and the nanostructure.

Despite extensive research, non-conventional semiconductor materials have shown poor transport properties which limit cell performance, and hence high performance solar cells must not rely on transport in these materials. For example, approaches in which the QDs replace dye in dye-sensitized solar cells or in which QDs exist in organic materials represent high risk long term approach, since the solar cell is controlled by the matrix, not the QD. This can be circumvented by developing selective energy contacts, which allow direct metal contact of the nanostructure. Thus, to implement either MEL or MEG mini-band transport solar cells in a low-cost fashion, optimum materials and device designs, selective energy contacts, and low-cost closely-spaced ordered QD arrays are all required.

An alternative approach to transport in nanostructured materials is to use photons to excite carries to the upper energy band. This process is used in quantum well and quantum dot intra-red photodetectors (QWIP and QDIPs). Once at this energy, carriers must be prevented from being captured back into the nanostructure. Transport in the barrier allows high performance provided that the barrier or matrix material surrounding the nanostructure has good transport properties, that there is a strong electric field, and that carriers are not transported in the nanostructure. These requirements limit the useful nanostructure configurations. To avoid transporting carriers in the nanostructure, the direction of transport of carriers should be perpendicular to the confinement of the nanostructure, which allows QD and QW structures, but not nanorods aligned parallel to the direction of light absorption.

Efficient multiple exciton generation (MEG) has been observed in semiconductor nanocrystal quantum dots (QDs) made from low bandgap materials, such as PbSe and PbS. The theoretical efficiency depends on the threshold energy of the multiple carrier generation process and on the number of electrons generated at this threshold. Up to three excitons are produced from one absorbed photon. The central challenge in utilizing there results in a practical solar cell require improving the modeling and understanding of impact ionization solar cells, incorporating the QDs into a film in sufficient concentration to provide high absorption, dissociating the photogenerated excitons and transporting the free electrons and holes to the device contacts, and identifying additional materials which show efficient exciton generation. These issues will be analyzed and optimized using solar cell structures such as dye-sensitized or organic approaches, and then applied to the ordered arrays using capillary process, which are developed in parallel.

Multiple quasi-Fermi level devices are further discussed below. MEL solar cells rely on a device structures in which multiple energy levels or bands are simultaneously radiatively coupled via both generation and recombination. Key challenges in their development are the demonstration simultaneous radiative coupling between all the bands and the development of optimum material systems and devices. Since the intersubband transitions required at the low energy photon range are well-documented and demonstrated in QW and QD intra-red photodetectors, the present invention uses the low-energy photons. Recent modeling has shown Sb-based QDs in the III-Vs, the Si/Ge system display the ability to implement an ideal MEL solar cell, and hence can be used as the equivalent of a three-stack below Si in order to achieve a 7J tandem. We first focus on development of realistic models for MEL solar cells structures, and the demonstration of three-radiatively coupled bands in both III-V MEL solar cells and Si/Ge MBE-grown solar cells. The III-V MBE grown devices are used to verify models and understand processes, and we focus on the Si/Ge QD approaches in the later phases, as these can be directly grown on the rear of the Si solar cell.

Selective energy contacts and low-cost, ordered quantum dot arrays are further discussed below. A low cost nanostructured solar cell requires both the use of an ordered array of QDs and selective energy contacts to the nanostructure itself. Engineering this semiconductor will require the development of a fundamentally new technology using regular arrays of quantum dots to achieve the desired band structure. Whitesides will first create arrays of small particles with good long-range ordering in hex-packed symmetry using a technique pioneered in his laboratory: the use of capillary forces to cause self-assembly. In this work, capillary motion from a retreating drop edge forces the dots into a regular pattern (a technique developed extensively and well-proven for formation of hex-packed 2D crystals of virus particles). The potential for using Langmuir-Blodgett techniques to fabricate crystalline colloid arrays at the air-liquid interface, and to transfer them to a substrate will also be considered.

Contacting quantum dot arrays is hard in general, and respecting the energy-selectivity makes it harder. A 20 nm metal film will typically exhibit 10% roughness. (2 nm is 3-4 monolayers). Evaporating metallic films on this layer does not solve the problems, due to damage to the underlying dot array and contact non-uniformity arising from surface tension. But, Au can be deposited as a thin film on an elastomeric surface (for example, a thin film of polydimethylsiloxane) to produce thin, uniform contacting layers: the mechanical compliance of the PDMS/Au produces usable atomic-level contacts. Related electrodes using a thin poly(aniline) film on the gold would probably make'even better electrical contacts, but need to be proven. Typically, the thin Au contacting layer (typically 20 nm thick) would be combined with an elastomer to allow precise spacing between the Au and the quantum dot array. These sorts of systems typically form tunneling contacts, and are the most reliable systems developed anywhere so far. In order to achieve an energy-selective contact to only the conduction band (and thereby prevent shorting to the valence band or miniband) requires development of a resonant tunneling contact. The present invention forms such a contact from a semiconductor—insulator—semiconductor—insulator—metal structure.

Nanostructured solar cells include structures which increase absorption. Due to the low volume of nanostructure material and the need to keep devices thin for transport reasons, these approaches have features that promote effective absorption. Light trapping is traditionally used in solar cells, and refers to an increase of the optical path length compared to the physical device thickness by confining the light to the active regions for multiple passes. While low levels of light trapping can be achieved with conventional reflectors (either metal or Bragg), higher light trapping in the thin structures proposed requires fundamentally new approaches. The present invention implements high absorption by designing photonic crystals which steer and reflect light, while allowing small feature sizes. The novel light trapping approach for the present invention comprises low-energy cells and involves the relatively new photonic band gap (PBG) materials technology. However, PBG technology is based on the use of lithographic fabrication approaches, and is therefore envisioned to be amenable to batch fabrication when it fully matures.

There are many acceptable approaches to process integration. An important guideline is to design to do the highest temperature processes first and then step down. Following are some of the ways that this can be accomplished. First we recall the basic approaches which are based on either a lateral design or a vertical design as shown. In both cases the static concentrator (and the dispersion element can be manufactured separately). They can be mated to the photovoltaic device in a final step. The device construction will start with a substrate. For these examples we will use glass. Following is an exemplary sequence:
1. Coat glass substrate with p+ silicon and re-crystallize
2. Deposit and form selective wavelength light trapping layer on the silicon.
3. Grow n-type silicon on the structure and re-crystallize.
4. Selective area growth of GaP buffer layer
5. Grow GaAsP solar cell
6. Grow GaInP solar cell
7. Grow InGaN solar cell
8. Form electrical contacts using ink-jet technology.
9. Deposit anti-reflection layer matched to the concentrator (and dispersion) optics.
   Next grow the bottom solar cell. Following is an example.
10. Coat another piece of glass with n-type silicon and re-crystallize.
11. Grow a Silicon: germanium alloy (of Si:Ge quantum dot)
12. Grow a silicon p+ junction
13. Deposit a light trapping structure
14. Form electrical contacts with ink-jet technology.

For a lateral junction device, one can use selective epitaxial growth for each of the high energy devices or layer transfer or a combination. A fundamental part of any solar cell is its anti-reflection (AR) coating. Existing AR coatings are not designed for low reflection over the entire solar spectrum, since solar cells presently do not convert over this entire range. By developing continuously variable index AR coatings, the present invention can decrease the reflectivity over the entire spectral range

The integration of optical design and semiconductor device architectures based on static concentration leads to a robust new design and technology space with MANY diverse technology options. This robust space will be expanded in Phase I with a focus on identifying those technology approaches that can lead to achievement of the program goals in a timely manner. The project will be managed according to the following strategy:
1. Design for the highest performance. The only cost criterion applied is the elimination of high fixed-cost components such as III-V or germanium substrates in the final product.

The present invention is divided into optics and high-, middle-, and low-energy devices. Each of these approaches has a core platform that uses proven high-performance materials in a low-cost format to achieve the program goals. Added to this are diverse approaches to expand the technology options as shown in FIG. 20 and FIG. 21.

Every part of the design will be scored on its ability to meet all required parameters: light absorption, charge separation, minority carrier collection, voltage generation, diode ideality (fill factor), affordability, materials compatibility, and manufacturability. Existing high performance solar cell technologies will be leveraged and new device architectures and process technologies will be added as they demonstrate (1) higher performance at a similar cost or (2) lower cost at the same performance.

The combination of the optical elements, the lateral and vertical solar cell architectures, the variety of solar cell materials systems (in the initial stages we investigate six material systems), and the different solar cell structures offers a rich design space. The co-design of the optics, integration, and solar cell structure means that the performance of the optical elements affects the integration strategy and the solar cell design. Thus, while the core approach consists of a 6J solar cell, divided into three energy ranges, the optics could make the solar cell design substantially different. For example, if the internally-tracking concentrators demonstrate manufacturability, reliability and low-cost, and concentration ratios above 150×, then only 4 to 5 junction are required. Again depending on the optical designs, these junctions may all be placed separately onto a substrate using the lateral architecture, or may be monolithically integrated. Alternately, even with these high concentrations, the proposed 6J solar cell could still be used to give efficiencies above 55%.

A central element of the optical/solar cell design of the present invention is the static concentrator. Although they are presently not used in terrestrial modules, this stems not from theoretical, technical or implementation issues, all of which have been demonstrated, but rather from the fact that terrestrial photovoltaics are presently bounded by assumptions which limit the commercial applicability of static concentrators, primarily relating to the difficulty in converting existing silicon production lines to new designs and integration processes.

The feasibility of the static concentrator is further enhanced by preliminary optical designs which show that existing optical fabrication technology allows both concentration and optical efficiencies that can meet the performance targets. Even the high efficiency concentrators rely on design expertise rather than new processing or manufacturing capabilities.

The method of the present invention comprises at least two paths to a static concentrator: (1) a lower concentration based on micro-lenses; and (2) a higher concentration approach which involves movable sheets of lenses. Assuming that both approaches yield similar optical efficiencies, the decision between the two is made on estimating the cost and manufacturability of each approach, integrating solar cell performance into the modules and comparing the costs of produced energy in $/kWh.

A second novel optical element of the present invention is the optics for the lateral solar cell architecture, which has greater technical risk, but also substantial pay-offs in terms of material flexibility, integration, and reliability. Furthermore, the lateral approach may be able to benefit other optical/photonic areas, such as multicolor detectors, such that a success in this area may experience co-development with another industry. The key strategy in reducing risk for the lateral optics and integration is the flexibility allowed in the number of “bins” into which the solar spectrum is split. A large number of bins makes both the optical design and the integration more difficult. While a smaller number of bins reduces the flexibility in material choice, since the number of bins is less than the number of junctions, several of the junctions should be grown monolithically for simplest assembly. The core approach involves development of three bins (high, medium and low energy), and designs, show in FIG. 7, demonstrate the viability of the lateral optics. There are two decision points in the designs for the lateral optics and integration. The first of these is made at the end of Phase 1, where we will identify two lateral/optical designs to proceed—one based on a high concentration/lateral design using micro-trackers, and the other on an all optical design. In Phase 2, the detailed performance characteristics, including experimental implementation, will determine the ability of each of these approaches to meet the cost, optical efficiency, and concentration targets. Unlike the device technologies, which have an inherent down-select after Phase 2, both optical approaches may be carried forward into Phase 3, as they may represent optimums for different applications.

The risk management for the multiple junction solar cell consists of using core approaches with proven high performance, and then exploiting the flexibility allowed by the integrated optical/solar cell design to minimize the cost. Further, for the high energy photons, which generate 66% of the total power, the present invention comprises multiple parallel approaches, such that—we need success in only one of the paths in order to achieve the overall objective of >50% efficiency solar cells.

Risk management for GaInAsP-based III-V solar cells grown on silicon is further discussed below. As described above, the central challenges in achieving high performance 3J solar cells in the GaInAsP material system are the growth of the ˜1.5 eV solar cell on a silicon substrate and secondly the development of a high band gap solar cell at ˜2.2 eV. The risk associated with the high band gap solar cell is low if it is grown on Si, as high band gap GaInP have lattice constants more closely matched to Si than to existing substrates.

An exemplary strategy is shown in Table 2, and involves selective epitaxial overgrowth of the GaInAsP-based layers on silicon. Such overgrowth regions have been shown to have higher crystallographic quality than if grown directly on a highly lattice-mismatched substrate. Further, depending on the growth approach used, selective growth has the advantages of reducing material cost. The decision point for perusing selective growth option will occur in Phase II, based on the demonstration of the individual band gap grown on silicon. Further, at this stage, the costs and manufacturability of the GaAs layer transfer, and will be evaluated to determine if alternate approaches are required.

TABLE 2

| Core Approach | Strategy 1 | Strategy 2 | Alternates |
|---|---|---|---|
| GaInAsP, grown on | GaInAsP, grown on | GaInAsP on GaAs or | Selective/ |
| Si solar cell | sacrificial Si | Ge, wafer re-use | overgrowth |
| Advantages: | Advantages: | Advantages: | Advanatages: |
| Low cost, high | Low cost Si wafer reduces | Presently used in high | Achieves good material |
| performance | manufacturability and cost | efficiency tandems | quality despite high |
| approach | issues with layer transfer | | lattice mismatch |
| Risk: | Risk: | Risk: | Challenges: |
| High quality lattice- | Optimization of buffer | High band gap GaInP | Development of new |
| mismatched growth | layer. | Layer transfer and | tools and processes. |
| for ~1.5 eV material | | wafer re-use in large | |
| on Si. | | scale production. | |

The potential risks of the III-nitride solar cells are higher than those of the GaInAsP material system due to the less developed state of the III-nitrides compared to conventional III-V materials. However, they are also undergoing intensive development from the LED industry and one factor mitigating the risk of using these materials is that the development is shared by the LED industry, and we can utilize the advances developed by this industry.

In addition to reduction of risk through the large developmental effort on nitrides from other industries and maintaining an open portal by which we can include other groups as our needs warrant, the present invention includes several additional risk management strategies. The risks associated with the III-nitrides are the use of a silicon substrate, the potential cost of growth approaches, and a potential link between high radiative lifetimes in the nitrides and difficulty in current collection. To manage the risk associated with the use of a silicon substrate, members of the group are presently involved in alternate substrate technologies.

The first alternate substrate is sapphire itself, which does not have intrinsically high materials costs and has been grown by low-cost approaches such as ribbon growth. An additional potential advantage of sapphire is that it has many ideal properties as an optical medium, and hence can allow novel integrated lens/solar cell concepts.

A second potentially low-cost substrate from a material cost standpoint is ZnO, which further has technical advantages that may be also be utilized by other industries developing the III-nitrides, such as high power. For example, the highly efficient molecular beam nature of MBE utilizes ˜80% of metallic source materials in nitride applications compared to less than 0.1% for MOCVD. The combination of these two issues leaves MBE at least 1000 times cheaper to operate for nitride applications.

A final potential risk in the nitrides is that high radiative emission shown for the nitrides, even for low minority carrier lifetimes, is due to localization of the carriers and may make collection of light-generated carrier difficult. While optimization of growth is one avenue inherently perused, which mitigates the need for quantum well structures or eliminates phase separation in the grown layers, the team's experience in QD and QW solar cells also has direct applicability here. Solar cell results have shown that high electric fields allow collection from carriers localized in quantum wells if the electric field is above a critical value. For these applications, since nanostructures do not increase the theoretical efficiency of the pn junction, the requirements of radiative coupling, impact ionization, etc do not apply.

The efficient conversion of low energy photons represents one of the more difficult issues in photovoltaics. However, the power contained in the lower portion of the spectrum is also relatively low (15% of the total) and our approach does not rely on dramatic improvements in the low photons energies. Consequently, the key risk associated with this process is not a technical risk, but rather the ability to demonstrate low-cost and manufacturability using devices and approaches based around materials used for thermophotovoltaic applications. The parallel approach to low photon energies use the Si/Ge system, in which we circumvent the previous performance limitations of indirect materials by new approaches to light trapping, which have been previously demonstrated but not applied to photovoltaics.

The approach at the most extreme end of the risk/benefits curve is to develop nanostructured virtual band gap solar cells. Despite the high risk, our approach has a high probability of success by (1) rigorous theoretical development of experimentally-based device models for nanostructured solar cells; (2) use of approaches which have demonstrated the required physical mechanisms; (3) development of ways to implement structures based on low-cost QD arrays.

The present invention further comprises development of experimentally-based device simulations is central to our approach since the optimum materials, device design rules, target efficiencies, and impact of non-idealities are all unknown. For example, inter-sub-band transitions, while used in IR detectors, have not been demonstrated in solar cells. The band structure effects, which do not affect the IR detector, cause large non-idealities in solar cells. However, they can be avoided by changing material systems. Existing modeling programs are not adequate since photovoltaic devices require multiple quasi-Fermi level separations (LEDs, lasers and detectors have a dominant transition), novel absorption mechanisms (such as multiple exciton generation), require calculation of both collection and forward bias currents (photodetectors and LEDs are dominated by one or the other), and include transport mechanisms such as hopping transport. We address this challenge by assembling a pre-eminent Team in modeling and characterizing nanostructured devices, with the Team spanning three universities and NREL, each with unique modeling/characterization experience.

In addition to the development of device design rules and optimum solar cell structures, the present invention provides low-cost approaches to implement structures of the present invention, including ways of fabricating the QD arrays, ways of contacting the nanostructured array, and ways of increasing absorption in the materials. Increasing absorption carriers the lowest technical risk, since photonic band gap nanostructures have already demonstrated the ability to control absorption and emission.

More aggressively but speculatively, a Bragg stack of Au+/colloid/Au− layers could cause more-or-less all photons to be captured by scattering and bouncing all of the photons inside the structure until they are absorbed by the quantum dots. Multiple layers of the Bragg stack can be formed by multiple nano fabrication steps, or by making large sheets of a single Au+/colloid/Au− layer and folding or rolling it to obtain the multiple layer structure. An additional risk management approach is to use core-and-shell structures. (Naomi Hillis at UT-Austin has published excellent work in this area.) For instance, a 20 nm layer of gold on glass beads can be monolayer-smooth and be formed into a perfectly crystal-like lattice with excellent monodisperse quality and long-range order. Further coatings can be used to separate the shells from adjacent beads and regulate bead-bead contact.

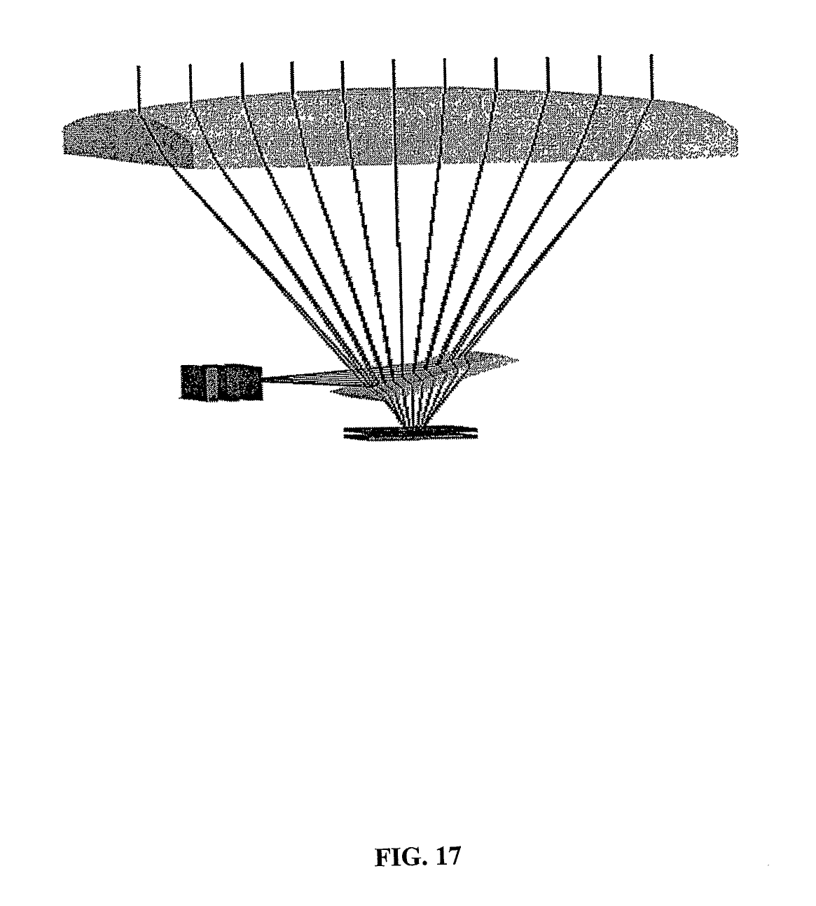

Optimum band gaps for a 6J solar cell are shown in FIG. 17, and demonstrates that the relaxation of series connection and lattice matching enables the development of the solar cell on a silicon platform. The Si platform provides many advantages, but importantly it is the only material capable of presently meeting both the efficiency target (in the wavelength range near its band gap) and the cost targets. The design also allows existing high performance materials to be used for two of the higher band gaps. A final advantage of low concentration is that the solar cell becomes less sensitive to defects, due to the increased operating point of the devices.

In addition, a static concentrator increases the power density on the solar cell, but does not need tracking, and is deployed and used identically to a 1-sun solar module by using a wide acceptance-angle optical element (typically non-imaging), which accepts light from a large fraction of the sky. Unlike a tracking concentrator, a static concentrator is able to capture most of the diffuse light, which makes up ˜10% of the incident power in the solar spectrum. The trade-off for the wider acceptance angle is a lower concentration If the application allows the module position to be manually adjusted at any point in the year, the maximum concentration increases. Depending on how long the module is to remain in a fixed position, the concentration can range from 10× to 200×.

Further, in the lateral configuration, a dispersive device is inserted in the optical path (e.g., a diffraction grating or prism) and the light is spread out in angle in the same way as occurs in a spectrometer. Unlike a spectrometer where there is a slit and therefore the size of the source is very small in the direction of the dispersion, the sun subtends a total angle of ˜0.5 degrees. This complicates the designs as is described below.

Another method of dispersing the light is to use dichroic mirrors where some wavelengths are reflected at a surface and others are transmitted as shown in FIG. 17. Commercial examples of dichroic mirrors are cold mirrors where visible light is reflected and infrared is transmitted. A dichroic system serves as the baseline design for the lateral approach. There are ongoing designs for the lateral optics, focusing on issues such as the choice between spherically and or cylindrically symmetric optics, the number of layers in the coating which are compatible with an affordable optical system, many optical designs have achieved over 90% optical efficiency.

The foregoing description of the invention illustrates and describes the present invention. Additionally, though the disclosure shows and describes only the preferred embodiments of the invention in the context mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described herein above are further intended to explain best modes known of practicing the invention and to enable others skilled in the art to utilize the invention in such, or other, embodiments and with the various modifications required by the particular applications or uses of the invention. Accordingly, the description is not intended to limit the invention to the form or application disclosed herein. Also, it is intended that the appended claims be construed to include alternative embodiments.

1-24. (canceled)

25. An apparatus for a photovoltaic solar cell, comprising:
a collector tile;
a spectral splitter comprising
a first prism
and
a second prism;
a static concentrator; and
at least one of a lateral architecture and vertical architecture using optical interconnects and solar device structures,
wherein the first and second prisms are at an input aperture of the collector tile, the first prism is very highly dispersive prism and second prism is low dispersion prism.

26. The apparatus of claim 16, wherein the spectral splitter is configured to divide at least one of light and a solar beam into high energy, mid-energy and low-energy regions.
